(19) United States
(12) Patent Application Publication
(10) Pub. No.: US 2021/0025945 A1
(43) Pub. Date: Jan. 28, 2021

(54) FIBER OPTIC SENSING APPARATUS, SYSTEM, AND METHOD FOR STATE OF CHARGE MEASUREMENT IN ENERGY STORAGE DEVICES

(71) Applicant: JINAN UNIVERSITY, Guangzhou (CN)

(72) Inventors: Tuan GUO, Guangzhou (CN); Wenjie MAI, Guangzhou (CN); Jiajie LAO, Guangzhou (CN); Peng SUN, Guangzhou (CN)

(73) Assignee: JINAN UNIVERSITY, Guangzhou (CN)

(21) Appl. No.: 17/067,748

(22) Filed: Oct. 11, 2020

Related U.S. Application Data
(63) Continuation-in-part of application No. PCT/CN2018/090809, filed on Jun. 12, 2018.

(30) Foreign Application Priority Data
Apr. 12, 2018 (CN) 201810325936.X

(51) Int. Cl. G01R 31/382; G01R 31/36; G02B 6/02

(52) U.S. Cl. CPC G01R 31/382; G02B 6/02085; G01R 31/3644

(57) ABSTRACT

An optical fiber sensing apparatus, system, and method capable of in operando and/or in situ monitoring a state of charge (SOC) of an energy storage device such as a capacitor or a battery is provided. The apparatus comprises an optical fiber having a surface plasmon resonance (SPR)-stimulating structure, exemplarily including a tilted grating in a core, and a SPR-active layer coating a cladding, of the optical fiber. The apparatus is configured such that when arranged in a close proximity with an electrode of the energy storage device, SPR waves are stimulated upon receiving an actuating light. Through analysis of signals of the SPR waves, the SOC of the energy storage device can be determined. The apparatus can also be utilized to capture non-SPR optical waves, analysis of which can further derive information such as temperature, pressure, strain, etc. of the energy storage device and/or be used for calibration.

### CROSS-REFERENCE TO RELATED PATENT APPLICATIONS

The present application is a continuation of International Patent Application No. PCT/CN2018/090809 filed Jun. 12, 2018, which claims priority to Chinese Patent Application No. 201810325936.X filed Apr. 12, 2018. The disclosure of all of these above patent applications are hereby incorporated into the present application by reference in their entirety.

### TECHNICAL FIELD

The present disclosure relates to a system and method capable of in situ and in operando monitoring a state of charge (SOC) of an energy storage device, and in particular to an optical fiber-based system and method for monitoring the SOC of an energy storage device such as a supercapacitor. The present disclosure belongs to the field of optical fiber-based electrochemical sensor design.

### BACKGROUND

The energy field on earth is facing various huge challenges. With the excessive consumption of fossil fuels such as petroleum, coal and natural gas and the excessive emission of greenhouse gases, the structure of energy supply for the human society is now developing from non-renewable energy sources to renewable energy sources.

Renewable energy produced by the sun, ocean and wind has been considered to be a cleaner technology than widely used fossil fuel-based energy sources. However, it is impossible to supply these forms of renewable energy steadily and continuously. Therefore, energy storage devices, such as supercapacitors and batteries, are commonly used for irregularly producing clean energy sources.

Among these, supercapacitors offer advantages such as fast-charging, high energy density and long life cycle storage solutions. According to the charge storage mechanism, supercapacitors can be generally classified into two types. One is the electric double layer capacitor (EDLC), which stores energy through charge absorption/desorption on the surface of an electrode. The other is the pseudocapacitor, also known as electrochemical supercapacitor, which stores energy by electron transfer between an electrode and an electrolyte through electrochemical reactions, i.e., the fast and reversible redox reactions occurring on the surface of the electrodes.

At present, a majority of existing detection methods for supercapacitors are substantially “off-line”. In other words, the state of charge (SOC) of a supercapacitor cannot traditionally be measured in operando, i.e. while the supercapacitor is in a charging/discharging working mode, but it needs to wait until the supercapacitor stops working, when an electrochemical workstation is commonly used to examine whether the electrochemical performance of the electrodes in the supercapacitor is attenuated or damaged. Examples of this approach includes cyclic voltammetry and galvanostatic charge-discharge method, etc., which are based on off-line measurements of current and voltage data to yield a “calculated capacity” that may not reflect the exact and instantaneous state of charge (SOC) of the supercapacitors. Furthermore, the reliability of those results can deteriorate over repeated cycling processes. (Conway BE 1999). A supercapacitor can be currently tested while it is in a working mode by means of a transmission electron microscope (TEM) or a cryoelectron microscope, but these instruments are very bulky and expensive, thus they are not practical for general applications, and they are especially not suitable for in situ measurement.

### SUMMARY

In light of these above issues associated with existing SOC monitoring technologies, the present disclosure provides a technical approach capable of monitoring SOC of energy storage devices such as supercapacitors in an in situ and in operando manner.

In a first aspect, an optical fiber sensing apparatus capable of in operando monitoring a state of charge (SOC) of an energy storage device is provided.

The optical fiber sensing apparatus comprises an optical fiber, which is provided with a surface plasmon resonance (SPR)-stimulating structure. The optical fiber sensing apparatus is characterized in that when it is arranged in a close proximity with an electrode of the energy storage device, surface plasmon resonance (SPR) waves are stimulated upon receiving an actuating light, and signals of the SPR waves contain information of the SOC of the energy storage device. Through the analysis of the signals of the SPR waves, the SOC of the energy storage device can be determined in an in operando or a real-time manner.

Herein the energy storage device can be of any type, and non-limiting examples include a capacitor, a supercapacitor (e.g. an electrochemical double layer capacitor or pseudocapacitor) or a battery (e.g. a lithium ion battery, lead-acid battery, sodium-sulfur battery, redox flow battery, fuel battery), etc.

Herein, the optical fiber can be of any type, such as glass-based optical fibers polymer-based optical fibers, single-mode fibers or multimode fibers, photonic crystal fibers, or microstructure fibers, etc.

Herein depending on the SPR-stimulating structure, the optical fiber in the optical fiber sensing apparatus can be a geometry-modified fiber, a grating-assisted fiber, or a specialty fiber, or a combination thereof. Preferably, the SPR-stimulating structure for the optical fiber can be a grating-assisted fiber, where the gratings can be long-period fiber gratings (LPFGs) or tilted grating such as tilted fiber Bragg grating (TFBGs), or a combination thereof. More preferably, the SPR-stimulating structure for the optical fiber is tilted gratings.

Herein the “actuating light” can be a light or a mixture of lights whose shedding into the optical fiber of the optical fiber sensing apparatus can stimulate the generation of surface plasmon resonance (SPR) waves. Preferably, the actuating light can be a phase-matched light having the capability of stimulating the maximum of the SPR waves, which typically meets certain conditions for the polarization direction and wavelength, etc.

Herein, the “close proximity with an electrode of the energy storage device” can be that the optical fiber sensing apparatus is aligned or attached onto an electrode of the energy storage device.

Herein, the term “in operando” can mean “real time”, and refers to the manner that the determination of the SOC of the energy storage device can be made when the energy storage device is working, and in an example of a supercapacitor, when the supercapacitor is charging or discharging.

According to certain embodiments of the optical fiber sensing apparatus, the optical fiber comprises a core and a cladding surrounding the core. The core is provided with a grating, and the optical fiber sensing apparatus further comprises an SPR-active layer coating an outer surface of the cladding. The SPR-active layer is configured to stimulate the generation of the SPR waves thereon upon receiving the actuating light.

Herein optionally, the grating is a tilted grating. The tilted grating can have an inclination angle of less than approximately 45 degrees, and more preferably the inclination angle can be approximately 5-25 degrees.

Herein, the actuating light can preferably comprise a phase-matched light. In other words, the phase-matched light may have a polarization direction that is substantially parallel to a writing direction of the tilted grating, and the phase-matched light may also have a wavelength that is capable of stimulating the SPR waves.

According to certain embodiments of the optical fiber sensing apparatus, the SPR-active layer comprises an SPR-active material. Herein optionally, the SPR-active material comprises at least one metal, at least one conducting metal oxide, at least one semiconductor material, at least one dielectric material, at least one two-dimensional material, or a combination thereof.

According to some embodiments, the SPR-active material comprises at least one metal, and optionally can comprise at least one of gold (Au), silver (Ag), platinum (Pt), aluminum (Al), or copper (Cu). In other words, the SPR-active layer may have a composition of a monometal of Au, Ag Pt, Al, or Cu, or have a composition of an alloy combining two or more of the above metals.

According to certain embodiments of the optical fiber sensing apparatus, the SPR-active layer has a thickness of approximately 20-80 nm, preferably of approximately 30-70 nm, and more preferably of approximately 40-50 nm.

According to certain embodiments, the optical fiber sensing apparatus further comprises a transition layer that is sandwiched between the outer surface of the cladding and the SPR-active layer. The transition layer is configured to increase adhesion between the SPR-active layer and the outer surface of the cladding. Optionally, the transition layer can comprise at least one of titanium (Ti), molybdenum (Mo), or chromium (Cr), and can have a thickness of 2-3 nm.

According to certain embodiments of the optical fiber sensing apparatus, one end surface of the optical fiber is coated with a mirror having a reflective surface facing inside the optical fiber. Herein, the end surface is typically the end surface that is opposing to the light-incident end surface of the optical fiber, and optionally, the mirror can be a metal reflective film having a thickness of more than approximately 200 nm.

According to certain embodiments, the optical fiber sensing apparatus further comprises a protective film layer coating an outer surface of the SPR-active layer. Optionally, the protective film layer can comprise at least one of Polyethylene (PE), Polypropylene (PP), Polytetrafluoroethene (PTFE), Soft ceramic, Diamond, TiO₂.

According to certain preferred embodiments, the optical fiber sensing apparatus is further characterized in that non-SPR optical waves (also “non-SPR waves” throughout the disclosure) are also generated from the optical fiber sensing apparatus upon receiving the actuating light, and signals of the non-SPR optical waves contain other important information, including information regarding certain electrical, physical, mechanical, chemical, and/or electrochemical properties of the energy storage device and/or information that can be used for calibration. As used herein, non-SPR optical waves may include core mode, ghost mode, cladding mode (including lower cladding modes and higher cladding modes), etc. The acquisition of the information of various physical and mechanic properties (e.g. temperature, strain, pressure, etc.) and the calibration through the analysis of non-SPR waves have been summarized in Guo T et al., 2016 and Guo T et al., 2017, whose disclosure is incorporated herein by reference in their entirety.

For example, through the analysis of the signals of the non-SPR waves, the physical property (e.g. temperature) of the energy storage device can be further determined in an in operando manner, and optionally, the determination of the SOC can also be calibrated using the signals of the non-SPR optical waves as an inherent reference.

In a second aspect, the present disclosure further provides an optical fiber sensing system that is capable of in operando monitoring a state of charge (SOC) of an energy storage device. The optical fiber sensing system comprises an optical fiber sensing apparatus according to any of the embodiments as described above, which is arranged in a close proximity with an electrode of the energy storage device. The optical fiber sensing system further comprises a light source apparatus, which is optically coupled to a first end of, and configured to provide the actuating light into, the optical fiber of the optical fiber sensing apparatus. The optical fiber sensing system further comprises a signal detection apparatus, which is optically coupled to the optical fiber of the optical fiber sensing apparatus and configured to obtain signals of the SPR waves therefrom so as to derive information of the SOC of the energy storage device.

Herein, optionally and preferably, the light source apparatus is configured to provide a phase-matched light as the actuating light, or the actuating light provided by the light source apparatus comprises a phase-matched light.

Herein the energy storage device can be of any type, and non-limiting examples include a capacitor, a supercapacitor (e.g. an electrochemical double layer capacitor or pseudocapacitor) or a battery (e.g. a lithium ion battery, lead-acid battery, sodium-sulfur battery, redox flow battery, fuel battery), etc.

According to some embodiments of the optical fiber sensing system, the light source apparatus comprises a light source, a polarizer, and a polarization controller, which are operably connected in a sequential manner. Herein, the light source is configured to provide an input light, the polarizer is configured to convert the input light into a polarized light, and the polarization controller is configured to adjust a polarization direction of the polarized light to thereby produce the actuating light.

According to some embodiments of the optical fiber sensing system, the optical fiber of the optical fiber sensing apparatus comprises a core and a cladding surrounding the core, the core is provided with a grating, the optical fiber sensing apparatus further comprises a SPR-active layer coating an outer surface of the cladding, and the SPR-active layer is configured to stimulate generation of the SPR waves thereon upon receiving the actuating light.

Herein optionally, the grating is a tilted grating, and the polarization controller is configured to convert the input light into a polarized light such that a polarization direction of the polarized light is substantially parallel to a writing direction of the tilted grating.

According to some embodiments of the optical fiber sensing system, the light source comprises a broadband source, and the signal detection apparatus comprises an optical spectrum analyzer.

According to some other embodiments of the optical fiber sensing system, the light source comprises a laser source, configured to provide a light with a wavelength matched to the SPR waves, and the signal detection apparatus comprises an optical detector which is configured to detect the signals of the SPR waves from the optical fiber sensing apparatus, and then to convert the SPR signals into electrical signals. Herein, optionally, the optical detector may convert the signals of the SPR waves into analog electrical signals, and the signal detection apparatus may further include an analog-to-digital converter, which is configured to convert the analog electrical signals into digital electrical signals.

According to some other embodiments of the optical fiber sensing system, a second end of the optical fiber of the optical fiber sensing apparatus is provided with a mirror having a reflection surface facing inside the optical fiber of the optical fiber sensing apparatus, and the sensing system further comprises an optical fiber circulator or an optical fiber coupler, optically coupled to the first end of the optical fiber of the optical fiber sensing apparatus. Herein the optical fiber circulator or an optical fiber coupler can be arranged between the light source apparatus and the optical fiber sensing apparatus along an input optical pathway and between the optical fiber sensing apparatus and the signal detection apparatus along an output optical pathway, and is configured to separate the input optical pathway and the output optical pathway.

According to some other embodiments of the optical fiber sensing system, the signal detection apparatus is further configured to obtain signals of non-SPR optical waves from the optical fiber sensing apparatus. Through the analysis of the signals of the non-SPR optical waves, certain physical property (e.g. temperature, pressure, strain, etc.) inside the energy storage device can be further determined in an in operando manner, and optionally, the determination of the SOC can also be calibrated using the signals of the non-SPR optical waves as an inherent reference

In a third aspect, the present disclosure further provides a method for in operando monitoring a state of charge (SOC) of an energy storage device utilizing an optical fiber sensing system according to any of the embodiments as described above. The method comprises the following steps:

(1) providing the optical fiber sensing system, such that the optical fiber sensing apparatus is arranged in a close proximity with one electrode of the energy storage device, each of the light source apparatus and the signal detection apparatus is optically coupled with the optical fiber sensing apparatus, and the light source apparatus provides the incident into the optical fiber sensing apparatus;

(2) obtaining, by means of the signal detection apparatus, signals of surface plasmon resonance (SPR) waves from the optical fiber sensing apparatus; and

(3) analyzing the signals of the SPR waves to thereby determine the SOC of the energy storage device.

According to certain embodiments of the method, the step (2) of obtaining, by means of the signal detection apparatus, signals of surface plasmon resonance (SPR) waves from the optical fiber sensing apparatus further comprises: obtaining, by means of the signal detection apparatus, signals of non-SPR optical waves from the optical fiber sensing apparatus from the optical fiber sensing apparatus.

Herein further optionally the step (3) of analyzing the signals of the SPR waves to thereby determine the SOC of the energy storage device further comprises: determining a temperature inside the energy storage device based on the signals of the non-SPR optical waves.

Herein further optionally the step (3) of analyzing the signals of the SPR waves to thereby determine the SOC of the energy storage device further comprises: determining the SOC of the energy storage device, based on the signals of the SPR waves using the signals of the non-SPR optical waves as an inherent reference for calibration.

In a fourth aspect, the present disclosure further provides a method for manufacturing the optical fiber sensing apparatus as described above in the first aspect.

The manufacturing method comprises:

1) providing an optical fiber; and

2) making an SPR-stimulating structure on the optical fiber.

According to certain embodiments, the SPR-stimulating structure comprises a grating in a core of the optical fiber, and the step (2) of the manufacturing method comprises the following sub-steps:

A) engraving the core of the optical fiber with a grating; and

B) coating a cladding of the optical fiber with an SPR-active layer.

Herein, the sub-step A) can be realized by means of an excimer laser and a phase mask, or by means of a double beam interference; and the sub-step B) can be realized by means of magnetron sputtering or by means of thermal evaporation deposition.

In order to increase the adhesion for the SPR-active layer and to release the residual stress in the coating process, after the sub-step B) of coating a cladding of the optical fiber with an SPR-active layer, the step (2) further comprises: performing an annealing treatment over the optical fiber coated with the SPR-active layer.

Herein optionally, the annealing treatment can have a condition of approximately 300° C. for more than 3 hours.

Throughout the disclosure, the term “optical fiber sensing apparatus” and “optical fiber sensor” are considered to be exchangeable, and the term “optical fiber sensing probe” is considered a sub-type of an optical fiber sensing apparatus.

Throughout the disclosure, the relatively term “approximately”, “about”, “around”, or alike, that is behind a number, is referred to as a description of an actual number that is within 5% of the indicated number. In one illustrating example, “approximately 1.00” can be interpreted that the actual number is between 0.95 and 1.05.

### BRIEF DESCRIPTION OF THE DRAWINGS

FIGS. 1A-1I respectively illustrate different SPR-stimulating structures for the optical fiber sensing apparatus according to different embodiments of the disclosure, with FIGS. 1A-1E showing the various geometry-modified fibers, FIGS. 1F-1G showing the various grating-assisted fibers, and FIGS. 1H-1I showing the various specialty fibers.

FIGS. 2A and 2B are respectively a perspective view and a cross-sectional view of an optical fiber sensing apparatus according to some embodiments of the disclosure.

FIGS. 2C and 2D respectively show two different embodiments of the optical fiber sensing apparatus provided in the present disclosure.

FIG. 3 is a block diagram of a transmission-mode optical fiber sensing system according to some embodiments of the disclosure.

FIG. 4 is a block diagram of a reflection-mode optical fiber sensing system according to some embodiments of the disclosure.

FIGS. 5A and 5B respectively show a block diagram of an optical fiber sensing system according to two different embodiments of the disclosure;

FIG. 6 is a schematic diagram of an optical fiber sensing system for in operando monitoring the state of charge (SOC) of an energy storage device according to certain embodiments of the present disclosure.

FIG. 7 illustrates the working principle of the optical fiber sensing probe in the optical fiber sensing system for in operando monitoring the state of charge (SOC) of an energy storage device according to certain embodiments of the present disclosure.

FIG. 8A shows a cyclic voltammetry (CV) response profile of a supercapacitor tested at a scanning rate of 10 mV/s.

FIG. 8B shows a relationship between the plasma resonance intensity/amplitude of an optical fiber sensing probe and the electric potential of a supercapacitor.

FIGS. 9A and 9B show the optical responding curves of the core-mode resonance and the SPR resonance detected by the optical fiber sensing probe that corresponds to a charging and discharging cycle in a CV response curve of a supercapacitor.

FIG. 10A shows the cyclic voltammetry response profiles of a supercapacitor at a series of different scanning rates.

FIG. 10B shows the electrochemical responding curves of the electric charges stored in the supercapacitor when the supercapacitor is under the cyclic voltammetry (CV) test at the series of different scanning rates in FIG. 10A.

FIG. 10C shows the intensity/amplitude change curves of SPR resonance detected by the optical fiber sensing probe when the supercapacitor is under a cyclic voltammetry charge-discharge test at the series of scanning rates (shown in FIG. 10A).

FIG. 10D shows the Galvanostatic charge-discharge (GCD) curves of the supercapacitor disclosed herein under a GCD test at different currents.

FIG. 10E shows the quantity change curves of the electric charges stored in the supercapacitor when the supercapacitor is under the GCD test at the different currents (shown in FIG. 10D).

FIG. 10F shows the intensity/amplitude change curves of the SPR resonance detected by the optical fiber sensing probe when the supercapacitor is under the GCD test at the different currents (shown in FIG. 10D).

FIG. 10G shows the Galvanostatic charge and voltage holding (GCVH) curves of the supercapacitor disclosed herein under a GCVH test at different high electric potentials.

FIG. 10H shows the quantity change curves of the electric charges stored or released by the supercapacitor when the supercapacitor is under the GCVH test at the different high potentials (shown in FIG. 10G).

FIG. 10I shows the intensity/amplitude change curves of the SPR resonance detected by the optical fiber sensing probe when the supercapacitor is under the GCVH test at the different high potentials (shown in FIG. 10G).

FIGS. 11A and 11B show the electrochemical surface-plasmon-resonance sensing principle and experimental demonstration with a gold-coated TFBG optical fiber sensor, with FIG. 11A showing the CV response of the supercapacitor during a polarizing cycle including positive and negative polarities and the resulting electronic polarizations of Au film, where (i) and (iii) are for two opposite polarizations at −0.8 V and +0.8 V, and (ii) for neutral state (0 V); and FIG. 11B showing the spectral response of P-polarized input, gold-coated 18° TFBG for the different electronic polarization states of the electrode, where the enlarged view (i.e. the “SPR mode” inset) is shown of the spectral change of the SPR coupled cladding mode used for monitoring (marked by a red asterisk “*”); and enlarged view (i.e. the “Core mode” inset) is shown of the spectrum near the core mode (Bragg) reference resonance.

FIGS. 12A-12C show detailed charging and discharging of the supercapacitor from 0 to +0.8 V, where FIG. 12A shows spectral response of the selected SPR resonance (the red arrow indicates the variation trend of the SPR spectral feature with time) and FIG. 12B shows unchanged core Bragg resonance. The electrochemical curve and the optical response are synchronously recorded. FIG. 12C shows Intensity change of the selected SPR resonance (dot) and the core Bragg resonance (block) corresponding to one cycle of the CV curve of the supercapacitors at a scan rate of 10 mV s−1 (shown in the inset). The symbol \textcircled{1} represents the process of charging. Conversely, the symbol \textcircled{2} represents the process of discharging.

FIGS. 13A-13L show comprehensive electrochemical measurements and the corresponding SPR response spectra, where FIG. 13A shows CV curves for the supercapacitor at scan rates of 10, 15 and 20 mV s−1, FIG. 13B shows stored charge calculated from CV curves, FIG. 13C shows the corresponding sensor SPR transmitted intensity change and FIG. 13D shows linear fit of the change of sensor SPR transmitted intensity vs. the maximum stored charges, where each data point is the average of three CV tests; FIG. 13E shows GCD curves at currents of 0.2, 0.3 and 0.4 mA, FIGS. 13F and 13G the corresponding stored charge and SPR response, and FIG. 13H shows linear fit of the averages from three GCD tests; FIG. 13I shows galvanostatic charge and voltage holding (GCVH) test, FIGS. 13J and 13L show similar data extracted as in FIGS. 13B-13D and FIGS. 13F-13H.

FIGS. 14A-14C respectively show repeat cycles of CV charge/discharge test responses (FIG. 14A), SPR responses for the cases of carbon fabrics with MnO₂ (FIG. 14B) and without MnO₂ (FIG. 14C).

FIGS. 15A-15L respectively show CV curves of MnO₂ based supercapacitor at different scan rates 400 mV s⁻¹ (15A), 300 mV s⁻¹ (15E), and 200 mV s⁻¹ (151) and corresponding SPR intensity variation versus time (15B), (15F), (15J), and GCD curves of MnO₂ based supercapacitor at different currents 4 mA (15C), 3 mA (15G), 2 mA (15K), and corresponding SPR intensity variation versus time (15D), (15H), (15L).

FIGS. 16A-16B show linear fits for the change of sensor SPR transmitted intensity versus the maximum stored charges under CV and GCD tests.

FIGS. 17A-17F Sensor responses in the charging/discharging cycling tests, with FIG. 17A showing 5 cycles of CV data and FIG. 17B showing the corresponding sensor SPR transmitted intensity; FIGS. 17C-17D same as FIGS. 17A-17B but for 3 cycles of GCD; FIGS. 17E-17F same, but for 3 cycles of GCVH.

FIGS. 18A-18F respectively show: experimental setup of a plasmonic fiber-optic sensing system for monitoring the SOC of supercapacitors (FIG. 18A); photographs of the configuration for the supercapacitor (FIG. 18B) and gold-coated fiber-optic sensing probe (FIG. 18C), SEM images of the MnO2 electrode (FIG. 18D) and the corresponding magnified image (FIG. 18E), and schematic of the measurement of the charge-discharge process of supercapacitors by a plasmonic gold-coated TFBG fiber-optic sensor (FIG. 18F).

FIG. 19 shows the sketch of the configuration of a plasmonic optical fiber sensor for in situ monitoring of supercapacitors.

FIG. 20: (Left) Reflection spectra of a mirror-ended TFBG optical fiber coated with 50 nm of gold and immersed in water: P-polarized incident light showing SPR near 1550 nm (red curve) and S-polarized incident light (black curve, no SPR observed); (Right) Simulated electric mode field profiles for two neighboring high order cladding modes: modes excited by P-polarized core mode input light have electric fields that are oriented predominantly radially at the boundary (upper), while modes excited from S-polarized input have predominantly tangential electric fields around the fiber cladding boundary (bottom). The color scale reflects the magnitude of the electric fields and the arrows their orientation. The transfer of energy from cladding mode to a surface plasmon shows up as a bright ring around the fiber cladding for P-polarized input.

### DETAILED DESCRIPTION

In the following, the inventions disclosed herein will be described in further detail in combination with embodiments and drawings that are attached herewith. It is noted that these embodiments impose no limitations.

In a first aspect, the present disclosure provides an optical fiber sensing apparatus that is capable of monitoring a state of charge (SOC) of an energy storage device in an in operando manner. Herein, the energy storage device can be of any type that utilizes an electrolyte, such as a capacitor, a supercapacitor (e.g. an electrochemical double layer capacitor or pseudocapacitor) or a battery (e.g. a lithium ion battery, lead-acid battery, sodium-sulfur battery, redox flow battery, fuel battery).

The optical fiber sensing apparatus can be arranged in a close proximity to an electrode of the energy storage device (e.g. one of the two electrodes in a supercapacitor) to thereby provide a means for measuring the SOC of the energy storage device. The optical fiber sensing apparatus comprises an optical fiber, which is configured to be able to stimulate or excite surface plasmon resonance (SPR) waves upon receiving an actuating electromagnetic radiation or an actuating light (e.g. polarized light) propagating in the optical fiber. Through analysis over the signals of the SPR, the SOC of the energy storage device can be determined.

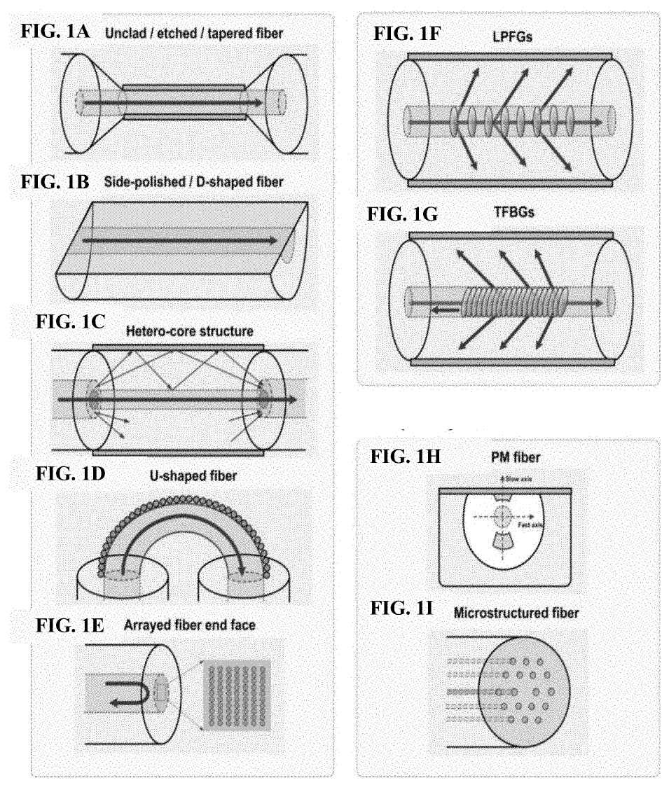

In the optical fiber sensing apparatus disclosed herein, the optical fiber can be configured to have a variety of different SPR-stimulating structures, as respectively illustrated in FIGS. 1A-1I.

According to some embodiments of the optical fiber sensing apparatus, such SPR-stimulating structure of the optical fiber may include certain geometry-modifications, which can include unclad/etched/tapered structure (illustrated in FIG. 1A), a side-polished/D-shaped structure (illustrated in FIG. 1B), a hetero-core structure (illustrated in FIG. 1C), a U-shaped structure (illustrated in FIG. 1D), an arrayed end face structure (illustrated in FIG. 1E).

According to some other embodiments of the optical fiber sensing apparatus that are preferred in the present disclosure, the optical fiber utilizes gratings engraved in a core, such as long-period fiber gratings (LPFGs, as illustrated in FIG. 1F) and tilted fiber Bragg grating (TFBGs, as illustrated in FIG. 1G), as the SPR-stimulating structure.

According to some other embodiments, the optical fiber of the optical fiber sensing apparatus may be a specialty fiber, such as PM fiber (as illustrated in FIG. 1H) or microstructure fiber (as illustrated in FIG. 1I).

These above different SPR-stimulating structures of an optical fiber is detailed in Caucheteur C, et al. 2015, whose disclosure is incorporated into the present application by reference in its entirety.

In the following, a detailed description is provided for the preferred embodiments of the optical fiber sensing apparatus where the optical fiber contained therein comprises a titled grating, such as TFBGs.

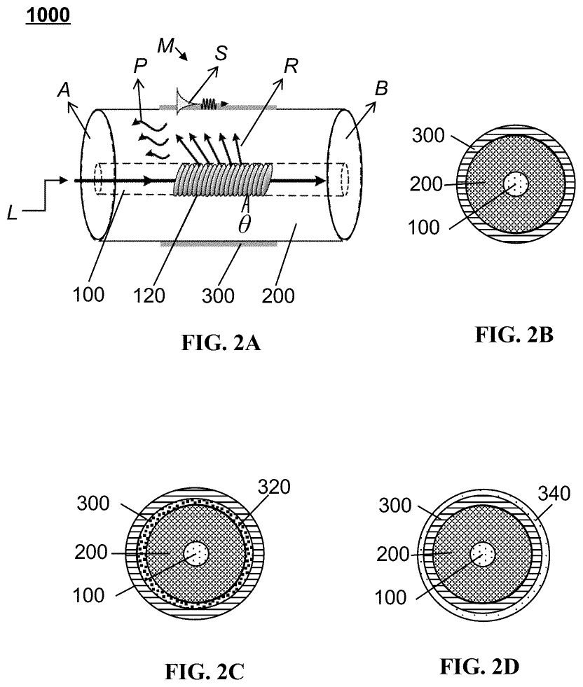

FIGS. 2A and 2B respectively illustrate a perspective view and a cross-sectional view of an optical fiber sensing apparatus according to some embodiments of the disclosure.

As illustrated, the optical fiber sensing apparatus 1000 includes a core 100 and a cladding 200, which are arranged coaxially to together form an optical fiber. An SPR-active layer 300 coats the outer surface of the cladding 200 of the optical fiber, with its outside surface facing a medium M, which can be a portion of an electrolyte that is in a close proximity of one electrode of an energy storage device (e.g. supercapacitor).

The core 100 of the optical fiber is provided with a tilted grating 120, i.e. a grating having an internal tilt angle θ (defined as an angle of each plane of the grating relative to a plane that is substantially perpendicular to the axis of the core 100). Upon an input light L entering from a first end surface A (i.e. first side surface) into the optical fiber and transmitting substantially along the core 100, the tilted grating 120 in the core 100 can reflect and/or refract the input light L into the cladding 200 of the optical fiber (the light such reflected or refracted is shown as “R” in the figure), exciting plasmon waves P in the cladding and surface plasmon waves S at an interface between the SPR-active layer 300 and the medium M.

In addition, the optical fiber sensing apparatus 1000 can also generate optical waves in the core 200 of the optical fiber (i.e. core-mode optical waves, not shown in the above drawings) which, if detected, can be used as an internal reference when doing the analysis of the surface plasmon waves S to thereby remove the unwanted influence, or interference, due to fluctuations from certain factors, such as those from the environment (e.g. temperature) or those from the sensing system (e.g. light source level). As such, the optical fiber sensing apparatus 1000 disclosed herein can have a feature of be capable of self-calibration.

The optical fiber sensing apparatus 1000 has a second end surface B (i.e. second side surface) opposing to the first end surface A (i.e. light incident surface), which could be configured as a light emitting surface (e.g. for a transmission-mode optical fiber), or as a light reflecting surface (e.g. for a reflection-mode optical fiber). In the latter case, a mirror comprising a metal reflective film can be arranged on the second end surface B with its light reflective surface facing inside the optical fiber, which is configured to reflect the electromagnetic radiation back towards the first end surface A of the optical fiber for detection by a signal detection apparatus. Such reflective configuration of the optical fiber on the second side surface B allows the optical fiber sensing apparatus 1000 to be conveniently used as sensing probe, and thus the reflection-mode optical fiber sensing apparatus is substantially an optical fiber sensing probe (see Example 1 for more descriptions). Optionally, the metal reflective film can have a thickness of more than approximately 200 nm.

Herein, the titled grating can have an inclination angle of less than approximately 45 degrees, and preferably of approximately 5-25 degrees. Optionally, the tilted grating can have a total axial length of approximately 5-50 mm, and preferably of approximately 10-20 mm. According to certain embodiments, the actuating light shedding into the optical fiber can have a polarization direction that is substantially parallel to a writing direction of the tilted grating. As used herein, the term “writing direction” or “inscription direction” refers to the direction of laser beam (such as high energy pulsed excimer laser) along the cross section of cylindrical optical fiber when the grating is formed in the fiber core. This means that the effective refractive index modulations along the fiber cross section is not uniform, in which the grating inscription direction is stronger. The polarization of input light should be parallel to that of grating inscription direction for SPR excitation with highest efficiency.

Herein, the SPR-active layer can comprise one or more SPR-active compositions. An SPR-active composition can be a composition with free electrons available for coupling into surface plasmon waves propagating along the surface of the material. Non-limiting examples of an SPR active composition include: a single material such as a metal (e.g. gold (Au), silver (Ag), platinum (Pt), aluminum (Al), and copper (Cu)) or a conducting metal oxide (e.g. indium tin oxide (ITO), but can also comprise a semiconductor material, a dielectric material, a two-dimensional material, or a mixture of two or more of the above single materials (e.g. an alloy, or a hybrid of a metal and a conducting metal oxide).

Furthermore, the SPR-active layer can have a thickness of approximately 30-60 nm, and preferably of approximately 40-50 nm. Optionally, the fabrication of the SPR-active layer 300 can be through magnetron sputtering or thermal evaporation deposition. In order to increase the adhesion for the SPR-active layer 300 and to release the residual stress in the coating process, after coating of the SPR-active layer, the optical fiber coated with the SPR-active layer can optionally further undergo an annealing treatment, for example, at approximately 300° C. for more than 3 hours.

According to certain embodiments of the optical fiber sensing apparatus, as illustrated in FIG. 2C, a transition layer 320 can be sandwiched between the outer surface of the cladding 200 of the optical fiber and the SPR-active layer 300, so as to increase the adhesion between the SPR-active layer 300 and the outer surface of the cladding 200 of the optical fiber. Herein, the transition layer 320 can comprise titanium (Ti), molybdenum (Mo), chromium (Cr), or any combination (i.e. alloy) thereof, and can have a thickness of approximately 1-10 nm, and preferably of approximately 2-3 nm. Optionally, the fabrication of the transition layer 320 can be through magnetron sputtering or thermal evaporation deposition.

According to certain embodiments of the optical fiber sensing apparatus, as illustrated in FIG. 2D, a protective film layer 340 is additionally configured to coat an outer surface of the SPR-active layer 300. Optionally, the protective film layer 340 can have a composition of Polyethylene (PE), Polypropylene (PP), Polytetrafluoroethene (PTFE), Soft ceramic, Diamond, TiO₂, and can have a thickness of approximately a thickness of approximately 1-10 nm, and preferably of approximately 2-3 nm.

It is further noted that in addition to capture the SPR signals, the optical fiber sensing apparatus described herein can also be utilized to capture other non-SPR optical signals such as the optical signals in the core (i.e. “core-mode” signals), and analysis over these non-SPR signals can derive information of certain parameters of the energy storage device, such as the inside temperature, and can also be used as an inherent reference to calibrate the fluctuations of system/environmental factors in the calculation of the SOC of the energy storage device.

In a second aspect, the present disclosure further provides an optical fiber sensing system, which comprises an optical fiber sensing apparatus according to any of the embodiments as described above.

In addition to the optical fiber sensing apparatus that is closely attached to an electrode of the energy storage device (e.g. supercapacitor) to be measured, the optical fiber sensing system further includes a light source apparatus and a signal detection apparatus, which are both optically and communicatively coupled with the optical fiber sensing apparatus, and are configured respectively to provide an actuating electromagnetic radiation (i.e. actuating light) into the sensing apparatus, and to obtain signals of the SPR waves stimulated on the surface of the SPR-active layer of the optical fiber sensing apparatus, so as to derive information of the SOC of the energy storage device.

Depending on the different working mode, the optical fiber sensing system has at least the following two configurations: a transmission mode and a reflection mode.

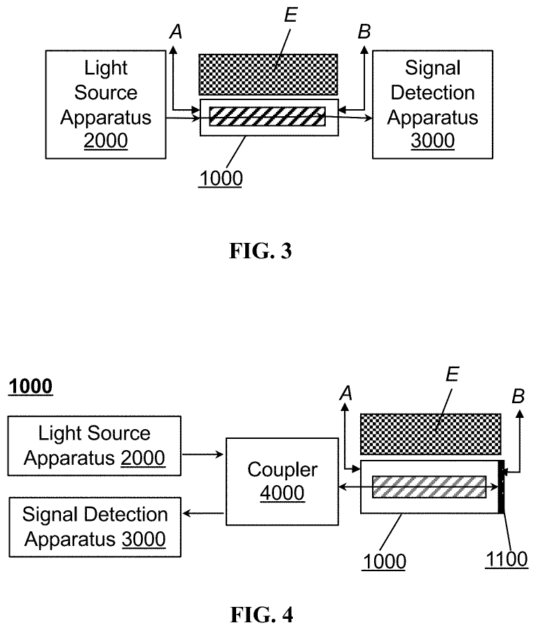

FIG. 3 is a block diagram of a transmission-mode optical fiber sensing system according to some embodiments of the disclosure. As shown, the optical fiber sensing system includes an optical fiber sensing apparatus 1000 that is attached closely to an electrode E of a supercapacitor (not shown in the figure). The optical fiber sensing apparatus 1000 is further optically and communicatively arranged between a light source apparatus 2000 and a signal detection apparatus 3000 along a direction of light transmission (as shown by the rightward arrows in the figure). In other words, the light source apparatus 2000 is optically coupled to a light-incident surface A of the optical fiber sensing apparatus 1000 and thus provide an input light shedding through the light-incident surface A into the optical fiber (as shown by the block with a pattern of inclining lines in the figure) of the optical fiber sensing apparatus 1000, whereas the signal detection apparatus 3000 is optically coupled to a light-emitting surface B of the optical fiber sensing apparatus 1000, and thus receives signals (i.e. signal of the SPR waves and core-mode optical waves, etc.) transmitted through the light-emitting surface B from the optical fiber sensing apparatus 1000.

It is noted that the transmission-mode configuration as above allows for multiplexing of more than one optical fiber sensing apparatus in one single optical fiber sensing system, in which the optical fibers of the more than one sensing apparatus share a common light transmission pathway from a single light source apparatus to a single signal detection apparatus. Optionally in the one single optical fiber sensing system, each of the more than one optical fiber sensing apparatus may be arranged in and configured to measure the SOC of, one corresponding energy storage device. Further optionally in the one single optical fiber sensing system, at least one of these multiplexed sensing apparatuses may be configured to characterize a parameter (e.g. a temperature, a humidity, a pressure, a target molecule, etc.) other than the SOC.

FIG. 4 is a block diagram of a reflection-mode optical fiber sensing system according to some embodiments of the disclosure. As shown, the light source apparatus 2000 and the signal detection apparatus 3000 are substantially arranged over a same side of the optical fiber sensing apparatus 1000, which is attached closely to an electrode E of a supercapacitor (not shown in the figure). Specifically, the light source apparatus 2000 and the signal detection apparatus 3000 are both optically coupled to a first end A of the optical fiber of the optical fiber sensing apparatus 1000, whereas a second end B is provided with a mirror 1100 comprising a metal reflective film that has a reflection surface facing to, and configured to reflect the light back towards, the first end A of the optical fiber. As such, the first end A is substantially a light-incident surface of the optical fiber, through which the input light provided by the light source apparatus 2000 can enter into the optical fiber of the optical fiber sensing apparatus 1000. Then after reflection at the second end B of the optical fiber by the mirror 1100, the reflected light can transmit back through the first end A to be received by the signal detection apparatus 3000. In order to separate an input optical pathway and an output optical pathway to thereby allow the signal detection apparatus to obtain the signals of the surface plasmon waves from the sensing apparatus without being influenced by the input light, the optical fiber sensing system disclosed herein further comprises an optical fiber circulator or an optical fiber coupler 4000 (only the optical fiber coupler is shown as “Coupler 4000” in the figure), which is arranged between the light source apparatus 2000 and the optical fiber sensing apparatus 1000 along the input optical pathway and between the optical fiber sensing apparatus 1000 and the signal detection apparatus 3000 along the output optical pathway. It is noted that optionally an optical fiber circulator can replace the optical fiber coupler 4000 to realize a similar optical path separation function.

Similar to the transmission-mode system, the reflection-mode sensing system can also realize multiplexing of more than one optical fiber sensing apparatuses, wherein the more than one sensing apparatus 1000 can be optically coupled one another in series and connected to the coupler 4000.

In any one embodiment of the optical fiber sensing system described above (regardless of transmission mode or reflection mode), the light source apparatus 2000 can include a light source, a polarizer, and a polarization controller (PC). Herein the light source can be a broadband source (BBS) or a laser source (LS, such as a tunable laser source (TLS)). Light emitted from the light source can be converted into a polarized light having a polarization direction substantially parallel to a writing direction of the tilted grating after the emitted light transmits through the polarizer and the polarization controller.

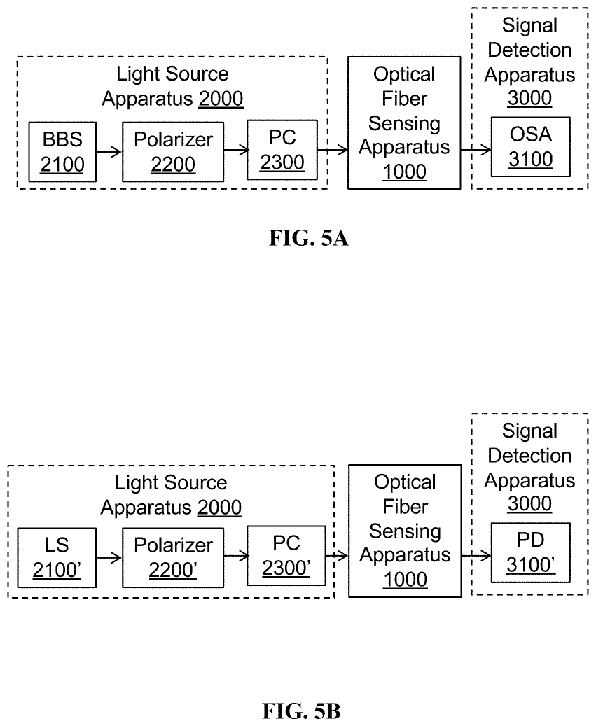

According to some embodiments of the optical fiber sensing system illustrated in FIG. 5A, the light source apparatus 2000 can include a broadband source (BBS) 2100, a polarizer 2200, and a polarization controller (PC) 2300, and in accordance, the signal detection apparatus 3000 comprises an optical spectrum analyzer (OSA, also known as “optical fiber spectrometer” or “spectrometer” throughout the disclosure) 3100. The broadband source (BBS) 2100 can provide a broadband input light, which can be converted, via the polarizer 2200 and the polarization controller (PC) 2300, into a polarized light with aforementioned polarization direction before it enters into the optical fiber of the optical fiber sensing apparatus 1000 so as to excite surface plasmon waves on the surface of the metal film thereof. The optical spectrum analyzer (OSA) 3100 is configured to analyze, via a spectral interrogation, the signals of the surface plasmon waves transmitted from the optical fiber sensing apparatus 1000 to quantify a wavelength shift and optical intensity change induced by the dielectric constant changes of the metal film and the surrounding medium over the optical fiber sensing apparatus 1000 and so as to derive information of, or characterize, the SOC of the energy storage device.

According to some other embodiments of the sensing system as illustrated in FIG. 5B, the light source apparatus 2000 can include a laser source (LS) 2100′, a polarizer 2200′, and a polarization controller (PC) 2300′, and in accordance, the signal detection apparatus 3000 comprises an optical detector (PD) 3100′. The laser source (LS) 2100′ is configured to provide an input light with a pre-determined narrow band, such as comprising a light with a second wavelength matching a predetermined first wavelength. A light with the predetermined first wavelength has been determined in advance to be able to produce one of the most sensitive modes of surface plasmon waves on the optical fiber sensing apparatus, upon being inputted into the optical fiber of the optical fiber sensing apparatus. The pre-determination can be performed utilizing the embodiments of the sensing system as illustrated in FIG. 5A, where the optical fiber sensing apparatus 1000 to be examined is coupled to a broadband source (BBS) 2100, a polarizer 2200, a polarization controller (PC) 2300, and an optical spectrum analyzer (OSA) 3100, and the broadband source (BBS) 2100 is configured to provide a broadband input light, whereas an optical spectrum analyzer (OSA) 3100 is configured to analyze at which wavelength the input light can generate one of the most sensitive modes of surface plasmon waves on the optical fiber sensing apparatus 1000.

The input light is further converted, via the polarizer 2200′ and the polarization controller (PC) 2300′, into a polarized light with aforementioned polarization direction before it enters into the optical fiber of the optical fiber sensing apparatus so as to excite surface plasmon waves on the surface of the metal film of the sensing apparatus 1000. The optical detector 3100′ is configured to detect the signals of the plasmon waves from the sensing apparatus 1000, and then to convert the detected signals of the plasmon waves into electrical signals. Optionally, if the electrical signals detected by the optical detector 3100′ is analog electrical signals, the signal detection apparatus 3000 can further comprise an analog-to-digital converter, which is configured to convert the analog electrical signals into digital electrical signals, based on which an interrogation can be performed over a quantification of intensity variations to thereby derive the information of the SOC of the energy storage device.

According to certain embodiments, the optical fiber sensing system may further include an electrochemical workstation, which may be electrically coupled to the energy storage device (e.g. supercapacitor) by operably wiring its electrodes (e.g. working electrode, counting electrode, and a reference electrode) with the electrode of the energy storage device.

Optionally in the optical fiber sensing system described herein, the signal detection apparatus can be configured to be able to capture non-SPR optical signals (e.g. “core-mode” signals). Analysis over these non-SPR signals can derive certain parameters of the energy storage device, such as the inside temperature, and can also be used as an inherent reference to calibrate the calculation of the SOC of the energy storage device.

In a third aspect of the disclosure, a method for in operando monitoring a state of charge (SOC) of an energy storage device utilizing the optical fiber sensing apparatus and system as described above is provided. The method includes the following steps:

S100: Providing an optical fiber sensing system.

Herein the optical fiber sensing system can be based on any one embodiment of the optical fiber sensing system described above, and comprises a light source apparatus, an optical fiber sensing apparatus and a signal detection apparatus. The optical fiber sensing apparatus is arranged to be in a close proximity with an electrode of the energy storage device. The light source apparatus and the signal detection apparatus are both configured to be optically and communicatively coupled with the optical fiber sensing apparatus. Further in this step, the optical path of the optical fiber sensing system is set up such that the light source apparatus is switched on to thereby provide an input light into the optical fiber sensing apparatus.

S200: Obtaining, by means of the signal detection apparatus of the optical fiber sensing system, signals of surface plasmon resonance (SPR) from the optical fiber sensing apparatus.

S300: Analyzing the signals of SPR to thereby determine an SOC of the energy storage device.

According to some embodiments of the optical fiber sensing system, the signal detection apparatus can further obtain optical waves in the core of the optical fiber (i.e. core-mode signals), which can be utilized to derive information of the temperature inside the energy storage device and/or as an inherent reference for calibration when doing the SPR analysis to thereby remove the unwanted influence (or interference) caused by fluctuations from certain factors, such as those from the environment (e.g. temperature) or those from the sensing system (e.g. light source level).

As such, according to certain embodiments of the method, step S200 may further comprise: obtaining, by means of the signal detection apparatus, core-mode signals from the optical fiber sensing apparatus.

Accordingly, step S300 may comprise: analyzing both the signals of the SPR and the core-mode signals to thereby realize at least one of the following: (1) determining a temperature inside the energy storage device; and (2) determining the SOC of the energy storage device, using the core-mode signals as an inherent reference for calibration.

According to some embodiments of the method, the optical fiber sensing system as illustrated in FIG. 5A is used for the in operando measurement of the SOC of the energy storage device. More specifically, the light source apparatus 2000 of the optical fiber sensing system comprises a broadband source (BBS) 2100, and the signal detection apparatus 3000 comprises an optical spectrum analyzer (OSA) 3100. As such, in step S100, the broadband source (BBS) 2100 substantially provides an input light with a broad band, and in step S200, the SPR signals are obtained by the optical spectrum analyzer (OSA) 3100. Correspondingly, the step S300 of analyzing the signals of SPR comprises: performing a spectral interrogation over the signals of the SPR to quantify a wavelength shift and optical intensity change induced by the dielectric constant changes of the metal film and the surrounding medium over the sensing apparatus so as to determine the SOC of the energy storage device.

According to some embodiments of the method, the optical fiber sensing system as illustrated in FIG. 5B is used for the in operando measurement of the SOC of the energy storage device. More specifically, the light source apparatus 2000 of the optical fiber sensing system comprises a laser source (LS) 2100′ configured to provide an input light with a predetermined first wavelength, which has been determined in advance such that it can produce one of the most sensitive modes of surface plasmon waves on the metal film of the optical fiber sensing apparatus, upon being inputted into the optical fiber of the optical fiber sensing apparatus. The signal detection apparatus 3000 correspondingly comprises an optical detector (PD) 3100′ and an analog-to-digital converter (A/D) 3200′. As such, in step S100, the laser source (LS) substantially provides an input light with the predetermined first wavelength. In step S200, the SPR signals are obtained by the optical detector (PD) 3100′ and the analog-to-digital converter (A/D) 3200′. More specifically, step S200 comprises:

S210: Converting, by means of the optical detector (PD) 3100′, the signals of the surface plasmon waves from the optical fiber sensing apparatus 1000 into analog electrical signals; and

S220: Converting, by means of the analog-to-digital converter 3200′, the analog electrical signals into digital electrical signals.

Further correspondingly, step S300 comprises: performing an interrogation over a quantification of intensity variations based on the digital electrical signals to thereby determine the SOC of the energy storage device.

According to some embodiments of the method, the optical fiber sensing system provided herein comprises more than one sensing apparatus, which are multiplexed (i.e. optically connected to one another in series and each comprising an optical fiber sharing a common electromagnetic radiation propagation pathway). As such, the step S100 may comprise: providing an optical fiber sensing system comprising more than one sensing apparatus. Correspondingly, the step S200 may comprise: differentially obtaining, by means of the signal detection apparatus, signals of surface plasmon waves from each of the more than one sensing apparatus. Further correspondingly, the step S500 may comprise: differentially analyzing the signals of the surface plasmon waves from the each of the more than one sensing apparatus.

In the following, two specific examples are provided to further illustrate and describe the optical sensing apparatus, system and method described above.

### Example 1

In this example, the titled gratings in the optical fiber of the optical fiber sensing apparatus comprise tilted fiber Bragg grating (TFBG), which can excite hundreds of modes with different sensitivities to the surrounding environment. By coating a metal film having a composition of gold, silver, etc. on the surface of the optical fiber, the cladding modes of the tilted FBG that meet the phase matching conditions can be coupled to the metal film to thereby form plasma resonance waves. The plasma resonance waves are very sensitive to changes of the dielectric constant, the electrode potential, and the density of electric charges of the metal film. Compared with traditional optical fiber sensing approaches with the evanescent field effect, the plasma resonance waves have higher detection sensitivity.

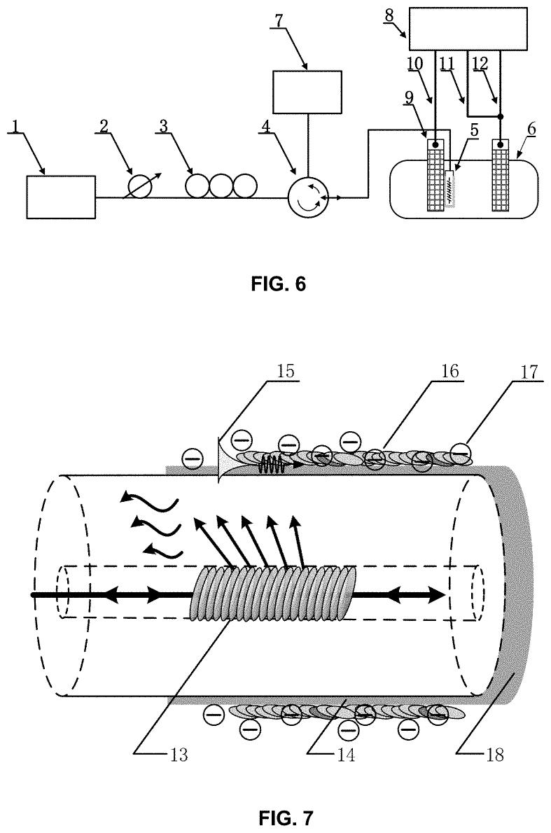

As illustrated in FIG. 6, this embodiment of the disclosure provides an optical fiber sensing system capable of in operando monitoring a state of charge (SOC) of an energy storage device, such as a supercapacitor herein, which includes a light source 1, a polarizer 2, a polarization controller 3, an optical fiber circulator 4, an optical fiber sensing probe 5, and an optical fiber spectrometer 7. The light source 1, the polarizer 2, the polarization controller 3, the optical fiber circulator 4 and the optical fiber sensing probe 5 are operably connected in a sequential manner. The optical fiber spectrometer 7 is operably connected with the optical fiber circulator 4. The optical fiber sensing probe 5 is arranged in a supercapacitor 6 to be monitored, and the supercapacitor 6 is operably connected with an electrochemical workstation 8.

In this embodiment, the supercapacitor 6 is filled with an electrolyte, and is provided with two supercapacitor electrodes 9. Part of each supercapacitor electrode 9 is disposed in the electrolyte. The optical fiber sensing probe 5 is tightly aligned or packaged tightly with one of the two supercapacitor electrodes 9. The electrochemical workstation 8 includes a working electrode 10, a counting electrode 11, and a reference electrode 12. The counting electrode 11 and the reference electrode 12 are electrically connected to one of the two supercapacitor electrodes 9 of the supercapacitor 6, and the working electrode 10 is electrically connected to another of the two supercapacitor electrodes 9 of the supercapacitor 6 through wiring.

As further shown in FIGS. 1 and 2, the optical fiber sensing probe 5 includes an optical fiber, which is engraved with a tilted grating 13 in the core. An outer surface of a cladding of the optical fiber is coated with a metal film 14 having a uniform thickness at a nanometer scale. The metal film 14 is not only the carrier for optical signals of the plasma resonance, but is also the transmission carrier for microcurrents. A light emitted by the light source 1 sequentially passes through the polarizer 2, the polarization controller 3 and the optical fiber circulator 4, and then enters into the optical fiber sensing probe 5. A cladding mode generated in the optical fiber of the optical fiber sensing probe 5 can be coupled to the metal film 14 that coats the outer surface of the cladding of the optical fiber to thereby stimulate a surface plasmon resonance (SPR) of the metal film 14. The optical fiber sensing probe 5 evanesces a light containing a plasma resonance wave 15 to an external environment outside the metal film 14, and the light interacts with the supercapacitor electrode material 16 on the surface of the supercapacitor electrode 9. At the same time, ions 17 in the electrolyte enter into the two-dimensional or three-dimensional space of the supercapacitor electrode material 16 to allow the redox reactions to occur and the density of electric charges near the supercapacitor electrode 9 to change, causing an energy loss of, and a wavelength shift of the resonance center of, the plasma resonance wave 13. This phenomenon can be captured and shown in the optical fiber spectrometer 7 such that the plasma resonance wave 15 exhibits as an absorption envelope in the reflection spectrum of the optical fiber spectrometer 7. When the supercapacitor is charged and/or discharged, the density of electric charges and ions near the electrode 9 change, and the amplitude of the absorption envelope of the plasma resonance wave 15 also changes accordingly, and the amplitude change has a corresponding relationship with the amount of electric charges stored in the supercapacitor, so the system can be used to simultaneously obtain the quantitative information of the electrochemical and optical signals, which can be used to determine the internal relationship therebetween.

In this embodiment, the light source 1 have an output spectrum of approximately 1500-1620 nm, and the range of the output spectrum of the light source 1 can optionally be configured to match with the range of the envelope of the reflection spectrum of the tilted grating in the optical fiber sensing probe 5.

In this embodiment, the tilted grating 13 of the optical fiber sensing probe 5 can be obtained by means of an excimer laser and a phase mask. It can be understood that it can also be obtained through a double beam interference. The tilted grating can have an inclination angle of approximately 5-25 degrees and a total axial length of approximately 10-20 mm.

In this embodiment, one end surface of the optical fiber in the optical fiber sensing probe 5 can be coated with a metal reflective film 18 with a thickness of more than approximately 200 nm. As such, the optical signals can be reflected by the metal reflective film 18 to realize the probe-type measurement.

Herein, the outer surface of the cladding of the optical fiber in the optical fiber sensing probe 5 can optionally be first coated with a transition layer of a chromium film having a thickness of approximately 2-3 nm by means of magnetron sputtering or evaporation, and can then be coated with a metal film having a uniform thickness at a nanometer scale. Preferably, the metal film 14 can be a gold film, which can not only effectively excite the plasma resonance waves, but also has good conductivity and stable physical and chemical properties. The metal film 14 can have a thickness of approximately 40-50 nm, which can ensure that the plasma resonance be excited with best efficiencies. After coating with the metal film 14, the optical fiber coated with the metal film 14 can be subject to an annealing treatment, preferably at approximately 300° C. for more than 3 hours, so as to increase the adhesion for the metal film 14 and to release the residual stress in the coating process.

This embodiment of the disclosure further provides an optical fiber-based method for in operando monitoring a state of charge (SOC) of an energy storage device. With a supercapacitor as an illustrating example for the energy storage device, certain embodiments of the method include the following steps:

S1: The optical fiber sensing probe 5 is tightly aligned or packaged with one of the electrodes 9 of the supercapacitor 9, and an electrolyte is filled in the supercapacitor 6.

S2: After setting up the optical path and the supercapacitor 6, the supercapacitor 6 is operably connected to the electrochemical workstation 8, and the electrochemical workstation 8 and the optical fiber spectrometer 7 are operably connected to a computer. After setting up relevant parameters, the polarization controller 3 is adjusted to allow the light incident into the optical fiber sensing probe 5 to be in a polarized state capable of exciting surface plasma resonance (SPR) on the metal film 14.

Herein, a light emitted from the light source 1 is converted into a polarized light after passing through the polarizer 2. A polarization direction of the polarized light is adjusted by the polarization controller 3 to be substantially same as (i.e. parallel to) a writing direction of the tilted grating 13 in the optical fiber sensing probe 5. The polarized light is configured to have a polarization direction that is parallel to the writing direction of the tilted grating 13. The polarization direction of the polarized light can be determined by the amplitude of the surface plasmon resonance peaks. Specifically, when the polarization direction of the polarized light is parallel to the writing direction of the tilted grating 13, the surface plasmon resonance peaks have a maximum amplitude.

S3: The supercapacitor is arranged under a natural condition, and the whole changing process of the state of change (SOC) of the supercapacitor during the charging process and the discharging process thereof for respectively storing an electric energy into, and releasing an electric energy from, the supercapacitor, is monitored by means of an optical and electrochemical approach. This step specifically includes:

The supercapacitor 6 is charged or discharged under the excitation of electrochemical workstation 8. When the supercapacitor is being charged, ions 17 in the electrolyte form an electrical double layer on the surface of the supercapacitor electrodes 9 to thereby store the electric energy. Accompanying an oxidation reaction on the supercapacitor electrode material 16, the electric charge is further accumulated on the supercapacitor electrodes 9, and the electric energy stored in the supercapacitor reaches to the maximum after the charging process is completed. When the supercapacitor is being discharged, a reduction reaction occurs on the supercapacitor electrode material 16, and the ions 17 that accumulate on the surface of the supercapacitor electrodes 9 to form the electrical double layer diffuse back into the electrolyte in a process that is opposite to the charging process.

During the whole charging and discharging process, the optical fiber sensing probe 5 monitors the real-time change of the state of charge (SOC) of the supercapacitor. The electrochemical workstation 8 and the optical fiber spectrometer 7 further record the whole process in which the state of charge (SOC) of the supercapacitor increases during charging and reduces during discharging, and then a corresponding curve can be drawn.

The slight disturbances of the energy from the light source, of the optical path system, and/or of the environmental temperature may bring errors to the detection results of the electrochemical workstation 8 and the optical fiber spectrometer 7. The core mode of an optical fiber is only sensitive to the temperature, and is substantially insensitive to the change of environmental refractive index and/or to the change of the dielectric constant of metal film 14. Therefore, by detecting the wavelength and the amplitude of the core mode of the optical fiber, the real-time detection of the temperature information and the light source energy can be realized. Through real-time measurement of the changes of the wavelength and amplitude of the core mode of the optical fiber, the errors can thereby be corrected, which can in turn eliminate the influence of the temperature change and the external interference on the detection result, so as to realize a self-calibration functionality.

S4: Under a manual condition, different electric potentials are applied to the supercapacitor 6 to control the polarity and quantity of the electric charges stored in the supercapacitor, which in turn controls the density changes of the electric charges on the surface of the optical fiber sensing probe 5, which can be detected through the intensity change of the cladding mode of the tilted grating 13 corresponding to the wavelength of the absorption envelope of the plasma resonance wave 15 modulated by the wavelength shift of the absorption envelope of the plasma resonance wave 15. As such, the information of electric charges that are stored in and/or released by the supercapacitor can be converted into electrochemical-optical information so as to allow the monitoring for the storage or release of electric charges in the supercapacitor.

When a positive potential is applied, the density of negative ions at the supercapacitor electrodes 9 that is tightly aligned with the optical fiber sensing probe 5 increases, and the metal film 14 is in a state of electron polarization; when a negative potential is applied, the density of positive ions at the supercapacitor electrodes 9 that is encapsulated with the optical fiber sensing probe 14 increases, and the metal film 14 is in an opposite state of electron polarization. When the supercapacitor is being charged, ions in the electrolyte enter the two-dimensional or three-dimensional space of the active oxidation complexes on the surface of the supercapacitor electrodes through electrochemical reaction, and a large amount of electric charges are thereby stored in the supercapacitor electrodes. When the supercapacitor is being discharged, these ions return to the electrolyte again, and the stored electric charges are released at the same time. The optical fiber sensing probe 5 can detect the density change of the electric charges to thereby determine the state of charge (SOC) of the supercapacitor.

The optical fiber sensing probe 5 evanesces the light containing a plasma resonance wave 15 to an external environment outside the metal film 14, and the light interacts with the supercapacitor electrode material 16 that is modified on the surface of the supercapacitor electrode 9. At the same time, ions 17 in the electrolyte enter into the two-dimensional or three-dimensional space of the supercapacitor electrode material 16 to allow the redox reactions to occur and the density of electric charges near the supercapacitor electrode 9 to change, causing an energy loss of, and a wavelength shift of the resonance center of, the plasma resonance wave 13. This phenomenon can be detected in the optical fiber spectrometer 7, with the specific changes shown in FIGS. 3(a-b).

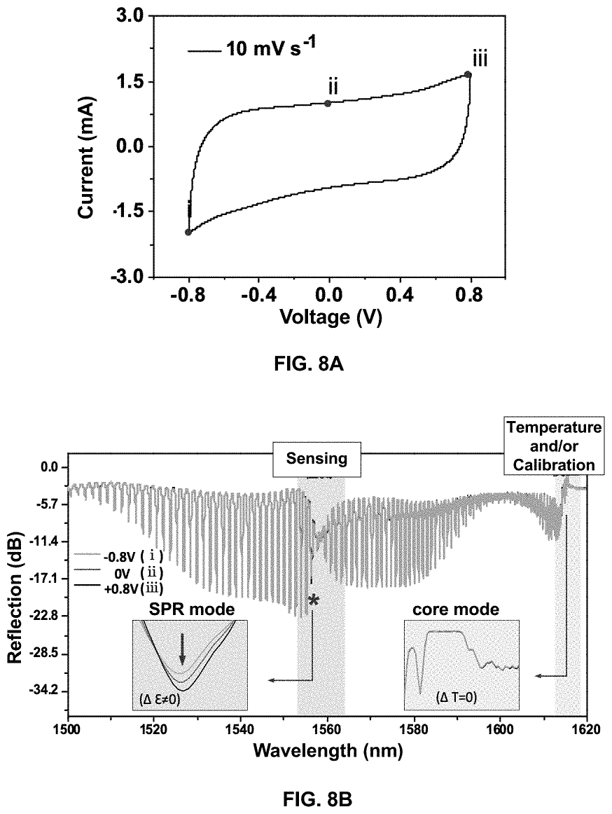

FIG. 8A shows a cyclic voltammetry (CV) response profile of the supercapacitor provided in the embodiment under a cyclic voltammetric (CV) charge and discharge test at a scanning rate of 10 mV/s excited by the electrochemical workstation. Correspondingly in FIG. 8B, the amplitude/intensity of the surface plasma resonance (SPR), which is indicated at the asterisk “*” corresponding to the absorption envelope of SPR, alters with the change of the electric potential of the supercapacitor (i.e. supercapacitor potential). As further shown in FIG. 8B, when the supercapacitor is under charge or discharge, the core mode of the optical fiber does not change, indicating that the detection process is carried out under the stable optical system and temperature environment conditions.

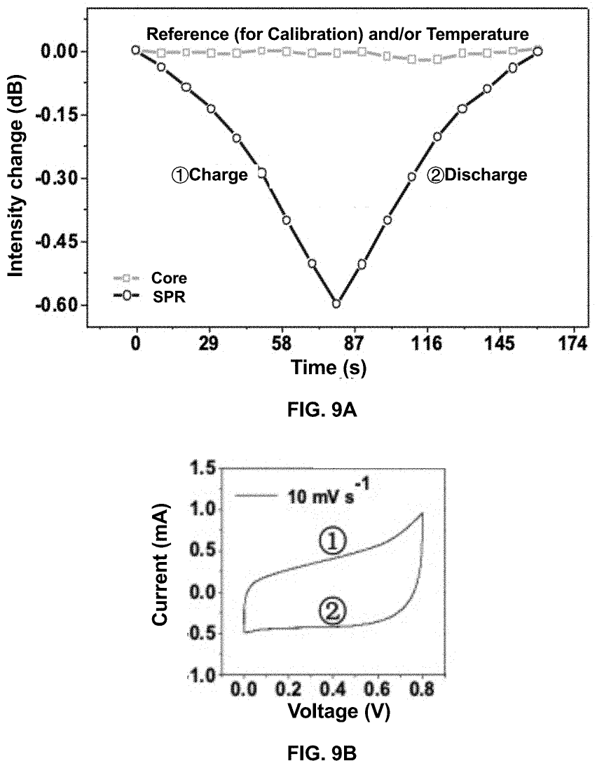

FIGS. 9A and 9B relatively completely records the change of the plasma resonance intensity during the process of charging and discharging of the supercapacitor. Such a change has a substantially same trend as the change of the electric charges that are stored in, or discharged from, the supercapacitor. In this process, the intensity change corrected by the core mode is also recorded, which is indicated by the upper curve (labelled as “Reference (for Calibration) and/or Temperature”) in FIG. 9A, indicating that the environmental temperature hardly changes in the whole monitoring process. In other words, the core mode can be used to correct the deviation of test results caused by the temperature and the unstable factors such as the light source and optical path.

As shown in FIG. 10A, when the supercapacitor is under cyclic voltammetric (CV) charge-discharge test at a series of scanning rates, the real-time quantity change of the electric charges stored or released by the supercapacitor is obtained by calculation of a CV curve (shown in FIG. 10B). As shown in FIG. 10C, the optical fiber spectrometer records a corresponding real-time curve of the SPR mode amplitude change. Similarly, FIG. 10D shows that the supercapacitor is under a Galvanostatic charge-discharge (GCD) at different currents, during which the real-time quantity change of the electric charges stored or released by the supercapacitor is obtained by calculation of a GCD curve (shown in FIG. 10E). As shown in FIG. 10F, the optical fiber spectrometer records a corresponding real-time curve of the amplitude change of the SPR mode to be tested when the supercapacitor is under the Galvanostatic charge-discharge (GCD) test. As further shown in FIG. 10G, the supercapacitor is under a Galvanostatic charge and voltage holding (GCVH) test at different high potentials, during which the real-time quantity change of the electric charges stored or released by the supercapacitor is obtained by calculation of a GCVH curve (shown in FIG. 10H). As shown in FIG. 10I, the optical fiber spectrometer records a corresponding real-time curve of the amplitude change of the SPR mode to be tested when the supercapacitor is under the Galvanostatic charge and voltage holding (GCVH) test at the different high potentials. In each of the three charge-discharge tests of CV, GCD and GCVH, the plasma resonance intensity in the optical fiber sensing probe has a substantially same trend as the real-time quantity change of the electric charges stored in, or released by, the supercapacitor, indicating that the real-time storage and discharge of the supercapacitor, which shows that the real-time state of charge (SOC) of the supercapacitor can be monitored by means of the optical signals of the optical fiber sensing probe.

Compared with existing technologies, the inventions disclosed herein have the following beneficial effects:

(1) The inventions disclosed in the present disclosure utilizes an optical fiber sensing probe as fine as hair which can both transmit optical signals and acquire optical wave information to thereby realize an in situ monitoring of the electric potentials in a supercapacitor during the charging process and/or the discharging process thereof and to realize an in operando recording of the quantity information of electric charges. It can be implemented into a relatively narrow and small space to thereby realize an in situ measurement, and can also be implemented in a simultaneous and real-time (or in operando) manner to measure changes of multiple parameters, such as a state of charge (SOC), an electric potential, a temperature, etc.

(2) The outer surface of the optical fiber sensing probe is coated with a metal film. The optical fiber sensing probe couples the energy of the surface plasmon resonance wave generated on the metal film to the external environment outside the metal film. The energy loss and the wavelength shift of the resonance center generated due to the interaction between the plasma resonance wave and the electrode material close to the surface of the metal film exhibits as an absorption envelope detected by the optical fiber spectrometer. The combination of the above multidisciplinary technologies (e.g. electrochemical technology, and the surface plasmon resonance technology) can realize the real-time and in situ monitoring of the charging and/or discharging process of a supercapacitor, which provides a new application prospect for monitoring the working conditions of various energy storage device.

(3) The high-sensitivity surface plasmon resonance technology can replace the traditional triangular prism having tens of millimeter-scale with a compact optical fiber sensing probe having only a hundred-micron scale, thus realizing the miniaturization of the sensing probe. Such a sensing probe can be inserted into a space that is difficult to reach or access to by traditional sensors in order for an in situ detection.

(4) In the present disclosure, the sensing probe and the signal-transmitting optical fiber shares a same optical fiber. Because of the low-loss characteristic of optical fibers, signals transmitted thereby almost do no attenuate even after a long-distance transmission, which can greatly improve the detection accuracy of a sensor. Thus, the system and method disclosed herein can be used to realize a long-distance, in operando, and real-time monitoring, thereby overcoming the defects associated with the existing technologies that require an offline testing.

(5) In the present disclosure, the metal film on the outer surface of the optical fiber cladding in the optical fiber sensing probe has a nanometer-level uniform thickness, which can ensure that the plasma resonance is stimulated with the best efficiency. The metal film is not only the carrier of the optical signal of the plasma resonance, but also has a good conductivity, thus it can also be used as a carrier for micro-current transmission.

(6) In the present disclosure, the end surface of the optical fiber in the optical fiber sensing probe is coated with a metal reflective film with a thickness of more than approximately 200 nm, and as such, the optical signals can be reflected by the metal reflective film to realize the probe-type measurement.

(7) In the present disclosure, the outer surface of the optical fiber cladding in the optical fiber sensing probe, before being coated with a metal film of nanometer thickness, can be coated with a transition layer of a chromium film with a thickness of approximately 2-3 nm by magnetron sputtering, so as to increase the adhesion between the metal film and the surface of the optical fiber cladding. After coating of the metal film, the optical fiber coated with the metal film can further undergo an annealing treatment, so as to increase the adhesion for the metal film and to release the residual stress in the coating process.

(8) In the present disclosure, the core mode of the optical fiber in the optical fiber sensing probe is sensitive only to temperature, but not to the environmental refractive index. Therefore, by detecting the optical fiber core mode, the real-time measurement of temperature information can also be realized, thereby eliminating the influence of temperature changes on the measurement results. At the same time, the amplitude change of the optical fiber core mode can be used to calibrate the interferences in the optical path, thereby conferring a functionality of self-calibration.

### Example 2

In this example, the optical fiber sensor has a tilted fiber Bragg grating (TFBG) imprinted in the core of a commercial single mode fiber typical of those used in telecommunications, provided with an additional nanometer-scale gold coating to support plasmon waves.

Its compact size makes it possible to be inserted into various hard-to-reach environments for in situ detection either as a hand-held probe or as a set of remotely operated devices fixed at various locations in the supercapacitor along a fiber-optic cable. Another particular advantage of the TFBG platform is a means to mitigate temperature cross-sensitivity: the optical spectrum of the devices used contains a feature corresponding to light remaining in the core of the fiber (the “Bragg resonance”) and thus is inherently insensitive to changes external to the fiber, apart from temperature and strain. Strain effects can be eliminated by suitable packaging while temperature effects can be calibrated out by using the Bragg resonance as a thermometer (a widely used application of FBGs). (Albert J, et al. 2013). For chemical changes immediately adjacent to the metal surface of the TFBG, however, the associated modification of the complex refractive index has a very strong impact on the phase velocity and attenuation of the SPR, an effect that is clearly reflected in the measured transmission of specific, high Q-factor resonances of the device. The sensor fabrication process, i.e., UV-light grating-inscription and surface nanometer-sized coating, does not affect the structural integrity of the fiber, hence ensuring the sensor robustness and reproducibility. Finally, the relationship between the sensor response and the SOC of the supercapacitors is found to be highly reproducible. The information provided by this kind of sensor will be beneficial to understanding and evaluating the performance of supercapacitors in active service.

1. Results

1.1 Optical SPR Response of TFBGs to the Charging/Discharging of Supercapacitors

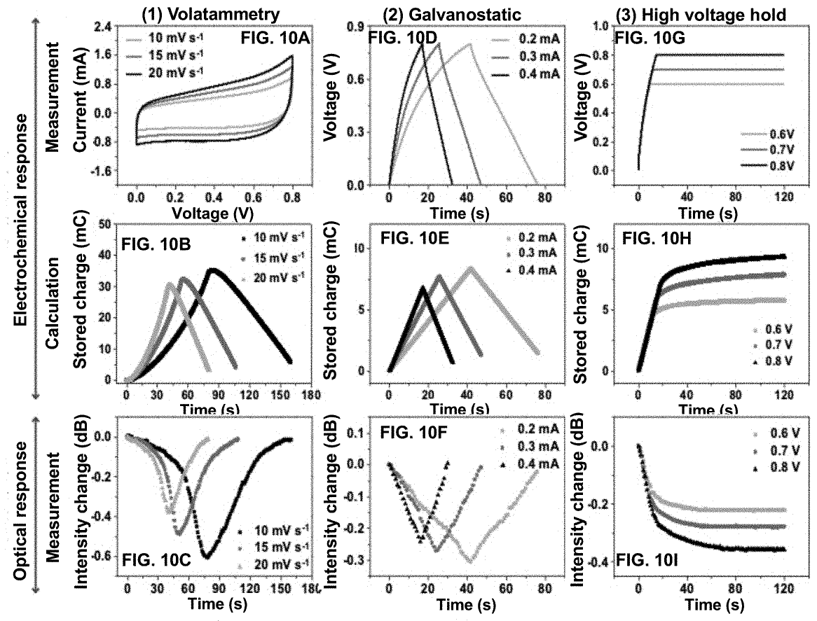

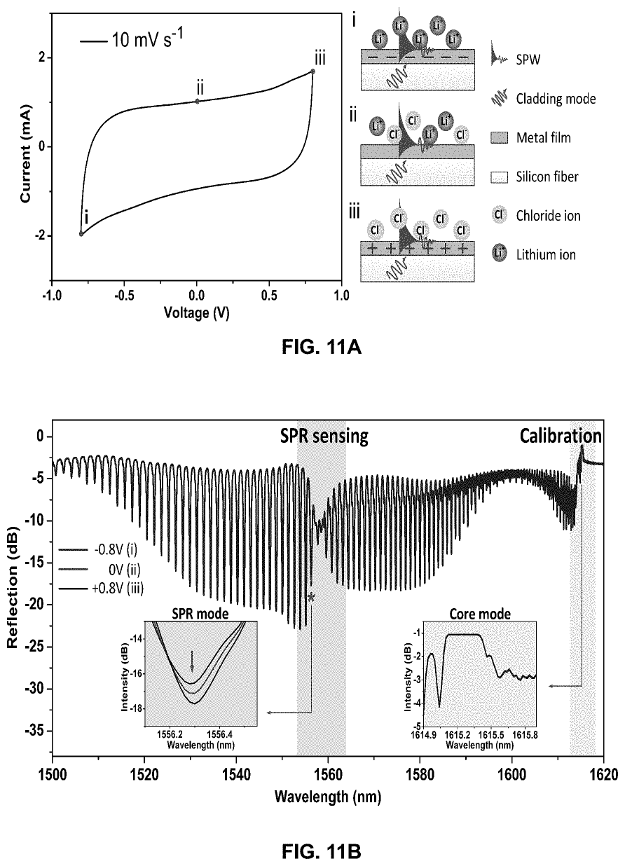

As discussed above, the position and amplitude of the SPR in the spectrum of a TFBG are directly related to the complex permittivity close to and in the metal film itself. Therefore, when the gold-coated optical fiber sensor is closely attached to the surface of the electrode, the change of charge density and ions distribution (corresponding to the SOC of supercapacitors) around the electrode can be directly monitored by reading the changes of the SPR spectrum of the sensor. FIG. 11A (left) presents the cyclic voltammetry (CV) curve measured in one cycle. The electronic polarization state of the metal film at three potential points, −0.8 V, 0 V, and +0.8 V, is considered. At point iii (+0.8 V), a large quantity of negative charges was attracted to the positive electrode. Thus, the gold film over the fiber was electronically polarized under the effect of interface capacitance in the supercapacitor. At point ii (0 V), the gold film was at the steady state and the supercapacitor was not charged. Finally, at point i (−0.8 V), the charging polarity on the electrode surface turns to positive so that an opposite electronic polarization would appear. During the CV curve measurements, optical SPR spectra were recorded simultaneously, and these results are shown in FIG. 11B. In such spectra, the “best” resonances to monitor are those within the SPR attenuation region (shaded in FIG. 11B) but not so attenuated as to become ill-defined and broadened. The resonance near 1556.3 nm (marked with an asterisk in FIG. 11B) was chosen here because it is clearly attenuated by transfer of energy to the plasmon, but it remains well-defined with a full width at half maximum on the order of 0.1 nm, yielding a resonance Q-factor of 15,000. As a first indication of the sensor response, the left inset of FIG. 11B shows a clear correspondence between the amplitude of the resonance and the electronic polarization of the gold layer: the resonance becomes deeper (shallower) for positive (negative) polarities, relative to the zero potential state. In addition, the right side inset provides a zoomed-in view of the Bragg resonance (yellow-shaded) during polarity cycling, demonstrating that the core mode is totally insensitive to the electrochemical changes, and therefore, its spectrum can be used as a power and wavelength reference to remove the impact of any system instability (or in the case of the wavelength, it acts as an in situ thermometer).

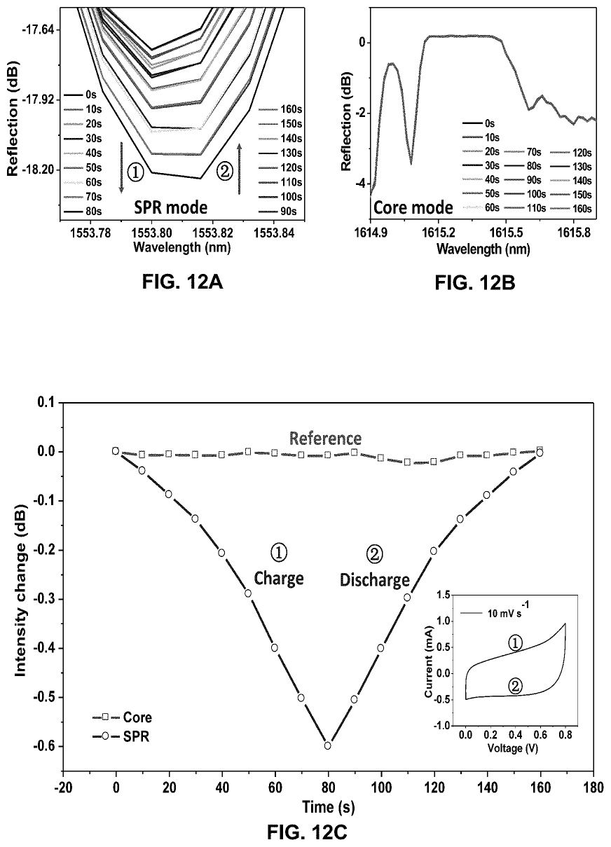

FIGS. 12A-12C present a more detailed investigation during a rapid CV measurement of a positive polarity cycle of the supercapacitor from 0 to +0.8 V over just one minute. FIGS. 2A and 2B show the SPR and Bragg resonances at various points during cycling while FIG. 2C summarizes the amplitudes of the resonances as a function of time. The SPR spectral response is clearly only related to the SOC of the supercapacitor regardless of whether the supercapacitor is charging or discharging (the Bragg resonance remains unaffected). It is now obvious that by correlating the spectral results to the recorded electrochemical curve (the CV measurement over one cycle shown in the inset of FIG. 2C), the real time in situ information of the SOC of supercapacitors can be obtained, as will be demonstrated.

1.2 State of Charge (SOC) Monitoring

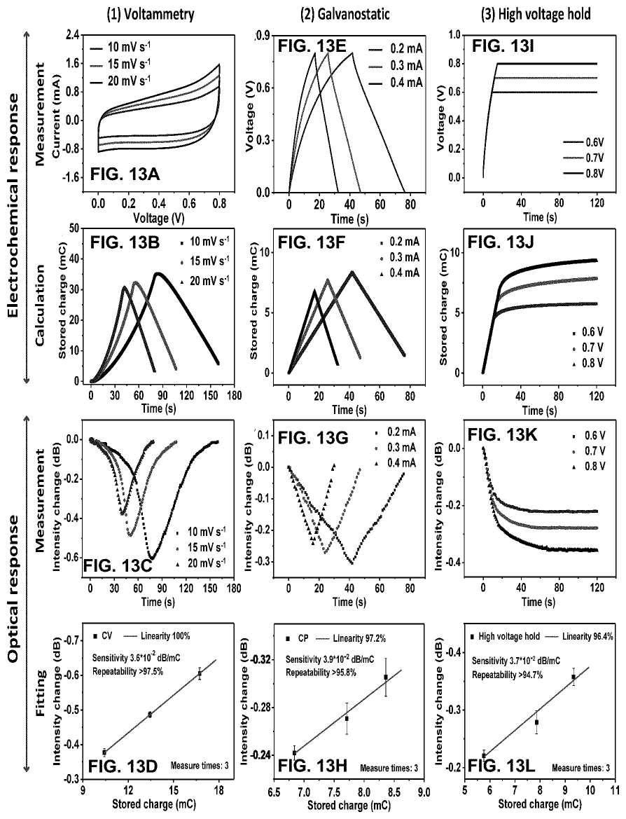

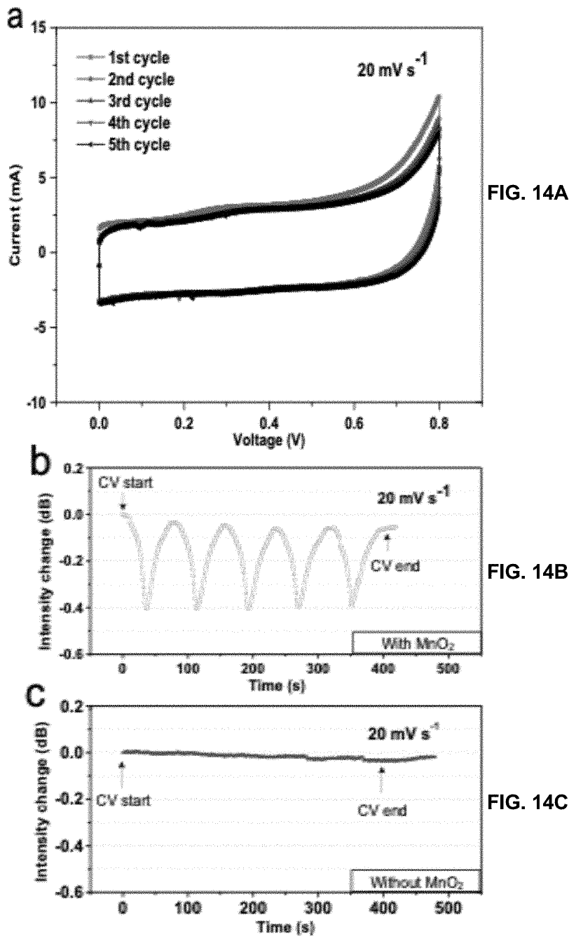

In order to verify the suitability of the proposed sensor for the monitoring of the SOC of a supercapacitor, three types of charging/discharging tests were employed: the normal voltammetry test, the galvanostatic charge/discharge test and the high voltage hold test. The results are presented in FIGS. 13A-13L and 14A-14F.

CV curves measured at three different scan rates, i.e., 10 mV s⁻¹, 15 mV s⁻¹ and 20 mV s⁻¹, were collected, shown in FIG. 13A, while the corresponding SOC was calculated from the current (C=∫Idt, where/is the instant current and t is the corresponding time in the CV curves), shown in FIG. 13B. The upper part of the CV curves (FIG. 13A) represents the charging process, in which the ions accumulate around the positive electrode of the supercapacitor and cause an increase of the stored charge. Both FIGS. 13A and 13B confirm that the SOC increases slightly with the scanning rate. This result is opposite to the general belief as both ion movement in the electrolyte and the intercalating process on the electrode take time. The SPR spectra of the developed sensor corresponding to the three voltammetry tests at different scanning rates were recorded. The variations of SPR intensity during the charging and discharging process were calculated and are presented in FIG. 13C. FIG. 13D shows the relationship between the maximum stored charge (Cₘₐₓ) and the corresponding SPR intensity variation (ΔSPR) for three repetitions of the measurements at each scan rate. A linear fit of the data indicates a relationship between C. (in mC) and ΔSPR (in dB) expressed as ΔSPR=−0.036×Cₘₐₓ−2.07×10⁻⁵, with a regression coefficient R² of 100% and repeatability of 97.5% (1−ΔSPRₑᵣᵣₒᵣ/ΔSPR_{average}). It should be noted that the above SPR intensity variation (ΔSPR) is essentially caused by the charging of the supercapacitor (the electrode), not the charging of the gold on the optical fiber. FIGS. 14A-14C clearly demonstrates this point by providing the experimental comparison results between the optical fiber SPR responses for supercapacitor monitoring with and without electrochemical capacitive material (MnO₂) on the surface of carbon fabrics.

Similar phenomena can be observed for the results obtained from the galvanostatic charge-discharge (GCD) tests (FIGS. 13E and 13F). When the high voltage of the charging process is fixed, the stored charge in supercapacitors is determined by the current flowing through the electrode. In this test, three currents were employed, i.e., 0.2 mA, 0.3 mA and 0.4 mA. When the current is lower, more charges can be gradually accumulated on the surface or in the inner layer of the pseudo-capacitive electrode. Thus, the stored charge at the current of 0.2 mA reaches the highest value among the three different currents. Additionally, the intensity change in the SPR response is higher because the corresponding stored charge is larger (FIG. 13G), strongly supporting the result of the CV measurement. A linear fit of the relationship between Cₘₐₓ and ΔSPR in this test, also based on three repetitions, results in the following: ΔSPR=−0.039 Cₘₐₓ+2.75×10⁻² (FIG. 13H), with R²=97.2% and a repeatability of 95.8%.

In the high voltage hold test, the sensor was subjected to a galvanostatic charge test with different ending voltages and then retained this voltage for 2 minutes. The testing results are shown in FIGS. 13I-13L. It can be noted from FIGS. 13I and 13J that the stored charge increases with the holding voltage between 0.4 and 0.8 V. For this case, the fitting result between Cₘₐₓ and ΔSPR is ΔSPR=0.037 Cₘₐₓ−4.68×10⁻³, with R²=96.4% and a repeatability of 94.7%.

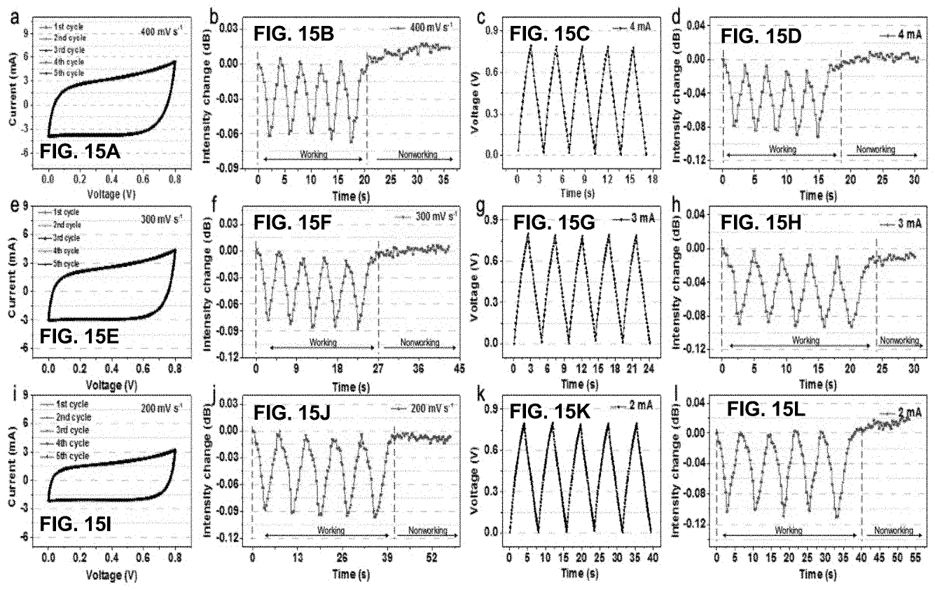

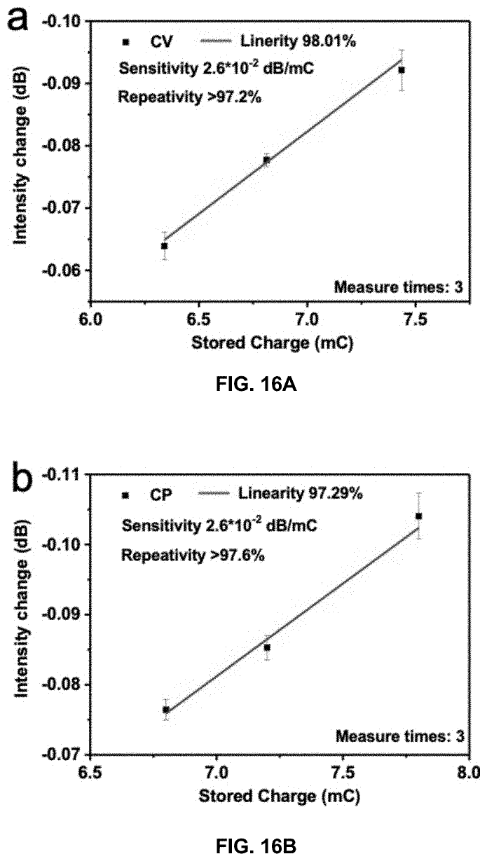

This method can also be used under faster charging and discharging speeds. As presented in FIGS. 15A-15L and 16A-16B, in situ CV and GCD measurements at much higher charging/discharging currents (2-4 mA) and faster scan speeds (200-400 mV s¹) were performed (both are 10 times higher than for the data in FIGS. 13A-13L). These results show that under the CV and GCD tests, the system in this example can effectively work at higher charging/discharging speeds. By calculating from the CV and GCD curves, the maximum SPR intensity variation corresponding to the maximum charge stored in the supercapacitor under different scan rates and currents was linearly fitted and presents excellent linearity and similar sensitivities (FIGS. 16A-16B). It should be noted that the value of sensitivity is a little lower than that under slow scan rates and lower current, as seen in FIGS. 13A-13L. This slight difference should be calibrated for different cases of in-field applications. The present interrogation speed is highly limited by the optical spectrum analyzer (because of interrogation based on spectrum acquisition). This problem can be definitely solved by using a real-time interrogation scheme based on power measurement in a narrow band of the optical spectrum. In this case, a tunable laser source (TLS) can be used as a source instead of a broadband source, together with a photodiode (PD) as detector and an analog-to-digital converter (A/D), to obtain the desired data (to replace the optical spectrum analyzer). The function of the TLS is to probe the transmission at the wavelength of the most sensitive mode of the fiber grating (the SPR mode here), determined by initial calibration with a spectrum analyzer. This technique relies on the principle of edge filtering so that the optical power change is produced as a result of the wavelength shift of the mode with respect to the fixed wavelength of the laser source.

The results in FIGS. 13A-13L indicate that the charge stored in the supercapacitor can be inferred from transmission changes at the SPR wavelength of the TFBG spectrum, regardless of the method used to determine the charge/ΔSPR relationship, estimated to be 3.7(+/−0.15)×10⁻² dB/mC (however, the value of 3.6×10⁻² dB/mC obtained by voltammetry appears to be more reliable in view of the fitting results). So, once a particular sensor is calibrated, it can be used to follow the SOC in a supercapacitor during its life cycle without having to interrupt operations to carry out electrical testing.

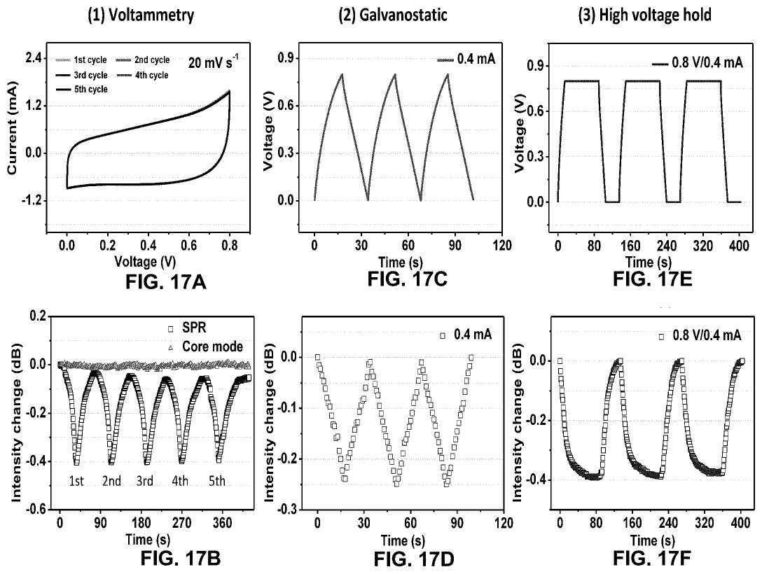

In order to further support the statement just made, repeated charging/discharging cycling tests were performed. In FIGS. 17A-17B, the CV curves of 5 cycles of voltammetry at a scan rate of 20 mV s⁻¹ and the corresponding sensor SPR intensity are presented. Similar measurements were carried out for GCD tests at 0.4 mA of current (FIGS. 17C-17D) and GCVH tests at 0.8 V and 0.4 mA (FIGS. 17E-17F). In all cases, little or no decay in the SPR response can be observed over the cycles presented (with the exception of a small drift of the zero charge SPR transmission intensity level in the CV test, with no apparent impact on the measurement of the maximum charged state near −0.42 dB).

### 2. Discussion

In this work, a novel method for the in situ monitoring of the capacity stored in supercapacitors was proposed for the first time. The method is based on a plasmonic TFBG sensor that is attached to one of the electrodes of the supercapacitor under testing. It was found that the SPR spectrum of the developed sensor clearly follows the charging and discharging processes of the supercapacitor. The CV, GCD and GCVH tests demonstrated that the SPR response of the developed sensor can be correlated quantitatively to the charge stored in the supercapacitor. Furthermore, the SPR response to stored charge changes was demonstrated to be stable over several cycles of charge and discharge. As a result, the proposed device provides a new approach in the study of the charging/discharging process of supercapacitors. In addition, since the TFBG sensor proposed is made from silica glass and gold metal and since it operates exclusively with light signals carried to and from the sensor by standard telecommunication grade optical fibers, with suitable packaging, it is expected to be robust enough to remain attached to the supercapacitor electrodes in operation and (following an initial calibration) to provide real-time remote monitoring of the SOC of supercapacitors used for power supply regulation from renewable energy sources.

### 3. Materials and Methods

3.1 Sensing System

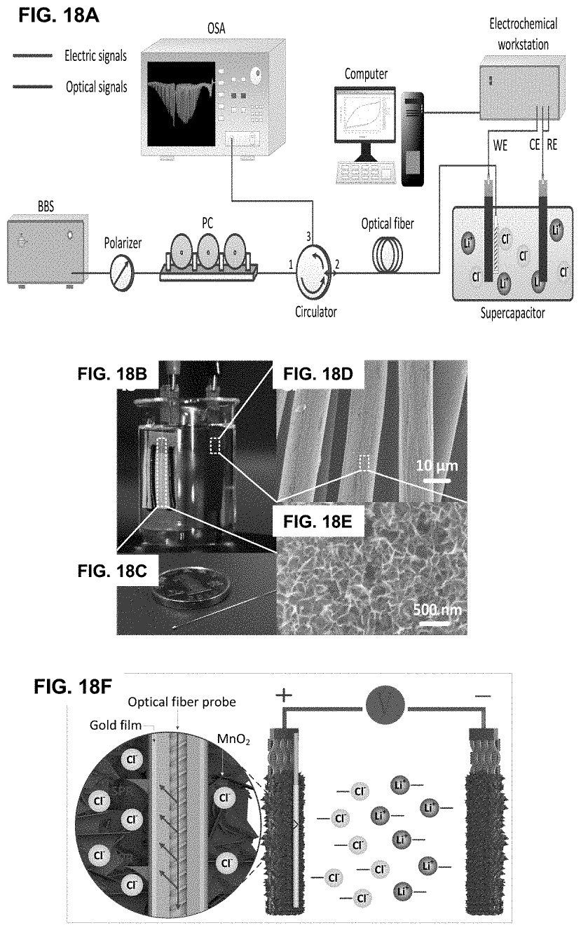

The all-fiber-coupled EC-SPR fiber-optic sensing system employed is shown in FIG. 18A and comprises a broadband light source (BBS) with bandwidth from 1250 to 1650 nm, a polarizer, a polarization controller (PC), a circulator, a plasmonic optical fiber sensing probe and an optical spectrum analyzer (OSA). An electrochemical workstation is used for performing conventional electrochemical measurements and collecting supercapacitor data to be correlated to the optical measurements. A computer was used to collect simultaneous data from both systems as the supercapacitor cycled through charge and discharge. FIG. 18B presents the detailed configuration of the measurement system containing a supercapacitor (two MnO₂@carbon fabric electrodes in liquid electrolyte, with an area of 3 cm² soaked in electrolyte) and a plasmonic fiber-optic sensing probe coated with a nanometer-scale gold film. The entire plasmonic fiber-optic sensing probe is very compact, with a size of 30 mm in length and 125 μm in diameter (FIG. 18C). The probe can be tightly attached to any electrode of the supercapacitor.

3.2 Supercapacitor

The scanning electron microscopy (SEM) images in FIGS. 18D and 18E show the morphology of the uniform MnO₂ nanosheets stacked over the surface of the carbon fiber fabric. A solution containing 0.1 M MnAc₂ and 0.1 M NaAc was used to provide Mn ions. The carbon fabric (area of 1×3 cm²) was soaked into the Mn ions solution and a constant current density of 1 mA cm′ was applied. The MnO₂ was synthesized by an electrodeposition method that used a three-electrode system with Ag/AgCl as the reference electrode and Pt as the counter electrode. The whole synthesis process was achieved in 5 minutes.

FIG. 18F shows the configuration of the supercapacitor and plasmonic optical fiber sensor. The supercapacitor used here is a pseudo-capacitor. It stores electrical energy on the basis of an electrical double layer effect over the material surface and fast bi-dimensional redox reactions in a very thin electrode surface layer. Sensing is based on the fact that the plasmon waves excited by the grating in the core of the optical fiber probe have a high percentage of their propagating power localized in a 1 μm thick layer above the metal surface. Therefore, when the fiber probe is positioned in the layer where the redox reactions occur, there are observable changes in the SPR optical spectrum.

3.3 Fabrication of TFBG-Based SPR Optical Fiber Sensor

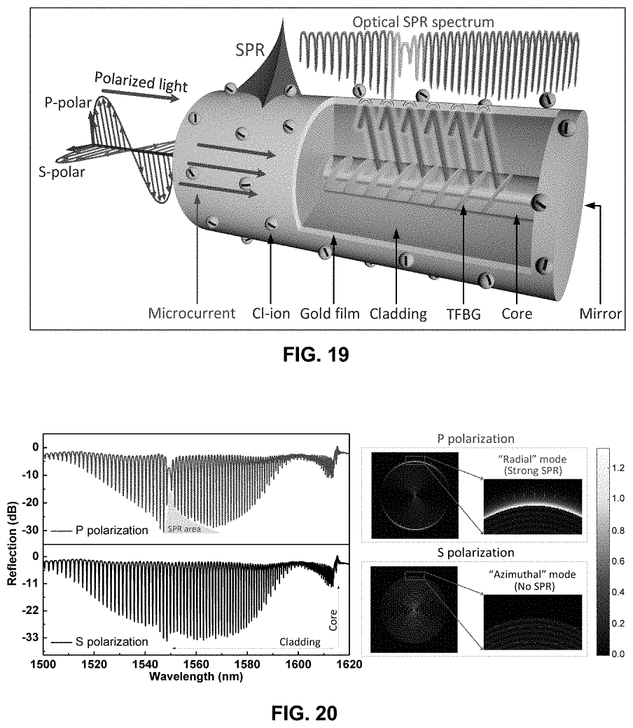

TFBG probes were manufactured in commercial photosensitive single mode fiber (provided by Corning Incorporated) using a well-established technique described in MacGriff C, et al. 2013. Specifically, the TFBG was manufactured using the phase-mask technique by shining UV light pulses from an excimer laser (at a wavelength of 193 nm and with a power of 30 mJ per pulse) onto the surface of a bare fiber, after passing through the diffractive mask where the desired grating pattern was etched. In this manner, a corresponding periodic modulation of the refractive index is formed in the fiber core. Contrary to the case for standard fiber Bragg gratings, the planes of the refractive index modulation were written with a pre-defined tilt relative to the longitudinal axis of the fiber (see FIG. 19, where the grating in the fiber core is colored in pink). The tilt of the grating is an important parameter that determines which set of cladding modes is excited: here, an 18 degree angle is chosen to maximize coupling to cladding modes that are suitable to transfer energy to surface plasmons in the aqueous solutions used for electrolytes in supercapacitors.

A 50 nm-thick gold layer of high surface quality was deposited on the above TFBG by sputtering as follows. First, a 2-3 nm buffer layer of chromium is deposited on the optical fiber surface to promote adhesion between the fiber and the gold. Second, gold is sputtered on top of the chromium while the optical fiber is rotated along its axis. This process ensures that the gold layer is uniform around the fiber, which helps in achieving clear SPR effects. Finally, the coated fiber is annealed for 3 hours at a temperature of 300° C. so that the gold coating has the desired morphology and is robust enough for sensing applications.

The responses of plasmonic TFBG devices are normally observed in transmission, which requires access to the sensor from both sides. For applications in small areas and, in particular, for this work, it is desirable to have single ended sensors located close to the end of a fiber, so that it can be inserted into tight spaces. Therefore, an additional (thicker) gold coating is deposited on the end of the fiber, cut a few mm downstream from the TFBG, to act as a broadband mirror with >90% reflectivity, which enables interrogation of the sensor in reflection. In the reflection measurement method, the Bragg resonance (reflection of the core mode upon itself, used for temperature compensation) appears as a spectral peak while cladding mode resonances appear as narrow troughs in the broadband reflection from the end mirror. FIG. 19 shows a cartoon representation of a typical sensor packaged for this work. This configuration also ensures that the sensor is strain free when a single attachment point is used to fix the sensor to the electrode surface.

3.4 Principle and Characteristics of TFBG-Based SPR Optical Fiber Sensors

Surface plasmon polaritons (SPPs) are near-infrared or visible-frequency electromagnetic waves that travel along a metal-dielectric or metal-air interface and decay exponentially away from the interface. The evanescent field of a fiber cladding mode can tunnel through a thin metal coating and transfer energy to an SPP wave of the outside interface of the metal when two necessary conditions are satisfied: (1) the propagation constant of the cladding mode equals that of the SPP for that particular combination of metal and surrounding medium; and (2) the polarization of the light must be perpendicular to the metal surface, i.e., TM-like. Only a small subset of the cladding modes of any fiber can meet these conditions.

The propagation constant β_{SPP} of SPP is expressed as:

$${β}_{SPP} = \frac{ω}{c} \sqrt{\frac{{ɛ}_{m} {ɛ}_{s}}{{ɛ}_{m} + {ɛ}_{s}}} \qquad ( 1 )$$

where c is the speed of light in vacuum, ω is the angular frequency of the light, and εₘ and εₛ are the complex relative permittivities of the metal film and the surrounding material adjacent to the metal interface where the SPP is located, respectively.

On the other hand, the propagation constants β_{clad,i} of cladding modes (labeled by the subscript i) in a standard fiber with a cladding diameter on the order of 100 times the wavelength can take a large, closely spaced set of values, and the associated fields have widely different polarization properties. The phase-match condition between propagation constants can be expressed as

β_{SPP}=β_{clad,i}=2πN_{clad,i}^{eff}/λ (2)

where the last equality introduces N_{clad,i}^{eff} which is defined as the effective index of the i^{th} cladding mode at wavelength λ. (Albert J et al., 2013).

Finally, the phase matching condition can be observed and measured with great accuracy from the transmission spectrum of a fiber grating because of the one-to-one relationship between effective indices (hence propagation constants) of modes and their resonance wavelengths in the spectrum, expressed by the following additional phase matching rule:

λ_{clad,i}=(N_{clad,i}^{eff}+N_{core}^{eff})Λ (3)

where N_{core}^{eff} is the effective index of the input core mode and Λ is the period of the grating (measured along the fiber axis, i.e., not equal to the distance between the tilted grating planes). As can be seen in the measured spectra in FIG. 20 (left), there are many such resonances corresponding to the set of modes supported by the relatively large cladding. A first discrimination between modes is provided by using polarized input core mode light. It was demonstrated that with input light polarized parallel to the inclination plane of the grating (P-polarized), the excited cladding modes have electric fields polarized radially at the surface of the cladding and can thus excite surface plasmons, while the orthogonal input polarization (S-polarized) excites tangentially polarized cladding modes that cannot couple to plasmons. This is clearly demonstrated in FIG. 20 by the fact that only the P-polarized spectrum (red curve) shows a characteristic attenuation of the cladding mode resonance amplitudes for wavelengths near 1550 nm (indicating that power has been “lost” or transferred from the cladding to the surface plasmon) and further by simulations of the electric field profiles for the two cases. The measured S-polarized spectrum (black curve) shows no such attenuation.

Having identified plasmon-coupled resonances in the spectrum at specific wavelengths, Equations 1-3 provide a direct link between these wavelengths and the permittivity of the medium just above the metal layer (εₛ). If that permittivity changes, the corresponding resonance position and amplitude will change as well. Such changes include the formation of a new material layer on top of the gold, such as in the well-known and widely applied affinity studies for biomolecules and also in the measurements of faradic currents and double layer charging currents in the metal film itself leading to charge density changes in the metal film and modifications of εₘ. The latter phenomenon is commonly named electrochemical surface plasmon resonance (EC-SPR), and it is a powerful tool to study and identify the electrochemical activity of the “surface” and “localized” charge state of the ions adjacent to the electrode interfaces. Simulations similar to those shown in FIG. 20 reveal that up to 70% of the light power of cladding modes phase matched to plasmons propagating as a bound wave in the external medium, while the “normal” evanescent waves of the cladding modes of bare fiber (with the same TFBG inside) can only carry between 2 and 5% of the mode power.

Finally, another factor important in the current device is that it operates in near infrared instead of the more commonly used visible wavelengths for SPR applications. This extends the penetration depth of the fields of plasmon waves from the 200-300 nm range to more than 1 μm, a more suitable distance for monitoring the electrochemical activities of ions just over the surface of the electrodes.

Taken together, the inventions provided in the present disclosure utilize an optical fiber sensing probe which is as fine as hair and can both transmit optical signals and acquire optical wave information to thereby realize a real-time or in operando monitoring of the electric potentials of a supercapacitor during the charging process and/or the discharging process thereof and to realize a real-time recording of the quantity information of electric charges. It can be implemented into a relatively narrow and small space to realize an in situ measurement, and can also be implemented in a simultaneous and real-time manner to measure changes of multiple parameters, such as a state of charge (SOC), an electric potential, a temperature, etc. In addition, the outer surface of the optical fiber cladding in the optical fiber sensing probe is coated with a metal film. The optical fiber sensing probe couples the energy of the surface plasmon resonance waves generated on the metal film to the external environment outside the metal film. The energy loss and the wavelength shift of the resonance center generated due to the interaction between the plasma resonance wave and the electrode material close to the surface of the metal film exhibits as an absorption envelope detected by the optical fiber spectrometer. As such, the combination of the above multidisciplinary technologies (e.g. electrochemical technology, and the surface plasmon resonance technology) can realize in operando and in situ monitoring of the charge and/or discharge of supercapacitors, thereby providing a new application prospect for monitoring the working conditions of various energy storage devices.

It is noted that the embodiments as described above represent only relatively better embodiments of the invention disclosed herein, and that the scope of protection for the disclosure is not limited to these above embodiments. Within the scope as provided in the present disclosure, any technicians familiar with the technical field who makes equivalent replacements, substitutions, or changes according to the technical schemes and the inventive ideas of the present disclosure, shall belong to the scope of protection of the present disclosure.

### REFERENCES

Conway B E. Electrochemical Supercapacitors: Scientific Fundamentals and Technological Applications. New York: Springer; 1999.
Albert J, Shao L Y, Caucheteur C. Tilted fiber Bragg grating sensors. Laser Photon Rev 2013; 7: 83-108.
Christophe Caucheteur, Tuan Guo, Jacques Albert, Review of plasmonic fiber optic biochemical sensors: improving the limit of detection, Analytical and Bioanalytical Chemistry, Vol. 407, No. 14, May 2015, 3883-3897.
MacGriff C, Wang S P, Wiktor P, Wang W, Shan X N et al. Charge-based detection of small molecules by plasmonic-based electrochemical impedance microscopy. Anal Chem 2013; 85: 6682-6687.
Guo T et al. Optics & Laser Technology 2016; 78:19-33.
Guo T et al. Journal of Lightwave Technology, Vol. 35, No. 16, Aug. 15, 2017.

1. An optical fiber sensing apparatus capable of in operando monitoring a state of charge (SOC) of an energy storage device, comprising an optical fiber provided with a surface plasmon resonance (SPR)-stimulating structure, wherein:
the optical fiber sensing apparatus is characterized in that when arranged in a close proximity with an electrode of the energy storage device, surface plasmon resonance (SPR) waves are stimulated upon receiving an actuating light, wherein signals of the SPR waves contain information of the SOC of the energy storage device.

2. The optical fiber sensing apparatus of claim 1, wherein the optical fiber comprises a core and a cladding surrounding the core, wherein the core is provided with a grating, and the optical fiber sensing apparatus further comprises an SPR-active layer coating an outer surface of the cladding, wherein the SPR-active layer is configured to stimulate generation of the SPR waves thereon upon receiving the actuating light.

3. The optical fiber sensing apparatus of claim 2, wherein the grating is a tilted grating having an inclination angle of less than approximately 45 degrees.

4. The optical fiber sensing apparatus of claim 2, wherein the SPR-active layer comprises an SPR-active material, wherein the SPR-active material comprises at least one metal, at least one conducting metal oxide, at least one semiconductor material, at least one dielectric material, or at least one two-dimensional material.

5. The optical fiber sensing apparatus of claim 4, wherein the SPR-active material comprises at least one of gold (Au), silver (Ag), platinum (Pt), aluminum (Al), or copper (Cu).

6. The optical fiber sensing apparatus of claim 4, wherein the SPR-active layer has a thickness of approximately 20-80 nm.

7. The optical fiber sensing apparatus of claim 2, further comprising a transition layer sandwiched between the outer surface of the cladding and the SPR-active layer, wherein the transition layer is configured to increase adhesion between the SPR-active layer and the outer surface of the cladding.

8. The optical fiber sensing apparatus of claim 1, wherein one end surface of the optical fiber is coated with a mirror having a reflective surface facing inside the optical fiber.

9. The optical fiber sensing apparatus of claim 2, further comprising a protective film layer coating an outer surface of the SPR-active layer.

10. The optical fiber sensing apparatus of claim 9, wherein the protective film layer comprises at least one of Polyethylene (PE), Polypropylene (PP), Polytetrafluoroethene (PTFE), Soft ceramic, Diamond, TiO₂.

11. The optical fiber sensing apparatus of claim 1, characterized in that non-SPR waves are additionally stimulated upon receiving the actuating light, wherein signals of the non-SPR waves contain information of at least one of a temperature, a pressure, or a strain inside the energy storage device.

12. An optical fiber sensing system for in operando monitoring a state of charge (SOC) of an energy storage device, comprising:
an optical fiber sensing apparatus according to claim 1, wherein the optical fiber sensing apparatus is arranged in a close proximity with an electrode of the energy storage device;
a light source apparatus, optically coupled to a first end of, and configured to provide the actuating light into, the optical fiber of the optical fiber sensing apparatus; and
a signal detection apparatus, optically coupled to the optical fiber of the optical fiber sensing apparatus and configured to obtain signals of the SPR waves therefrom so as to derive information of the SOC of the energy storage device.

13. The optical fiber sensing system of claim 12, wherein the light source apparatus is configured to provide a phase-matched light.

14. The optical fiber sensing system of claim 12, wherein the light source apparatus comprises a light source, a polarizer, and a polarization controller, operably connected in a sequential manner, wherein:
the light source is configured to provide an input light;
the polarizer is configured to convert the input light into a polarized light; and
the polarization controller is configured to adjust a polarization direction of the polarized light to thereby obtain the actuating light.

15. The optical fiber sensing system of claim 14, wherein the optical fiber of the optical fiber sensing apparatus comprises a core and a cladding surrounding the core, wherein the core is provided with a grating, and the optical fiber sensing apparatus further comprises a SPR-active layer coating an outer surface of the cladding, wherein the SPR-active layer is configured to stimulate generation of the SPR waves thereon upon receiving the actuating light.

16. The optical fiber sensing system of claim 15, wherein the grating is a tilted grating, wherein the polarization controller is configured such that a polarization direction of the polarized light is substantially parallel to a writing direction of the tilted grating.

17. The optical fiber sensing system of claim 14, wherein the light source comprises a broadband source, and the signal detection apparatus comprises an optical spectrum analyzer.

18. The optical fiber sensing system of claim 14, wherein:
the light source comprises a laser source, configured to provide a light with a wavelength matched to the SPR waves; and
the signal detection apparatus comprises an optical detector, configured to detect, and to convert into electrical signals, the signals of the SPR waves from the optical fiber sensing apparatus.

19. The optical fiber sensing system of claim 12, wherein:
a second end of the optical fiber of the optical fiber sensing apparatus is provided with a mirror having a reflection surface facing inside the optical fiber of the optical fiber sensing apparatus; and
the sensing system further comprises an optical fiber circulator or an optical fiber coupler, optically coupled to the first end of the optical fiber of the optical fiber sensing apparatus.

20. The optical fiber sensing system of claim 12, wherein the signal detection apparatus is further configured to obtain signals of non-SPR waves from the optical fiber sensing apparatus, wherein signals of the non-SPR waves contain information of at least one of a temperature, a pressure, or a strain of the energy storage device.

21. The optical fiber sensing system of claim 12, wherein the energy storage device is a capacitor or a battery.

22. A method for in operando monitoring a state of charge (SOC) of an energy storage device utilizing an optical fiber sensing system according to claim 11, comprising:
providing the optical fiber sensing system, such that the optical fiber sensing apparatus is arranged in a close proximity with one electrode of the energy storage device, each of the light source apparatus and the signal detection apparatus is optically coupled with the optical fiber sensing apparatus, and the light source apparatus provides the actuating light into the optical fiber sensing apparatus;
obtaining, by means of the signal detection apparatus, signals of surface plasmon resonance (SPR) waves from the optical fiber sensing apparatus; and
analyzing the signals of the SPR waves to thereby determine the SOC of the energy storage device.

23. The method of claim 22, wherein:
the obtaining, by means of the signal detection apparatus, signals of surface plasmon resonance (SPR) waves from the optical fiber sensing apparatus further comprises:
obtaining, by means of the signal detection apparatus, signals of non-SPR waves from the optical fiber sensing apparatus from the optical fiber sensing apparatus;
and
the analyzing the signals of the SPR waves to thereby determine the SOC of the energy storage device further comprises:
determining a temperature inside the energy storage device based on the signals of the non-SPR waves.

24. The method of claim 22, wherein:
the obtaining, by means of the signal detection apparatus, signals of surface plasmon resonance (SPR) waves from the optical fiber sensing apparatus further comprises:
obtaining, by means of the signal detection apparatus, signals of non-SPR optical waves from the optical fiber sensing apparatus from the optical fiber sensing apparatus;
and
the analyzing the signals of the SPR waves to thereby determine the SOC of the energy storage device comprises:
determining the SOC of the energy storage device, based on the signals of the SPR waves using the signals of the non-SPR waves as an inherent reference for calibration.
